(19) United States
(12) Patent Application Publication
(10) Pub. No.: US 2010/0033268 A1
(43) Pub. Date: Feb. 11, 2010

(54) PIEZOELECTRIC RESONATOR DEVICE

(75) Inventors: Minoru Iizuka, Kakogawa (JP); Akinori Maemori, Kakogawa (JP); Yosuke Morimoto, Kakogawa (JP)

Correspondence Address: MOTS LAW, PLLC, 1629 K STREET N.W., SUITE 602, WASHINGTON, DC, 20006-1635, US

(73) Assignee: Daishinku Corporation, Kakogawa (JP)

(21) Appl. No.: 12/518,506

(22) PCT Filed: Dec. 25, 2007
(86) PCT No.: PCT/JP2007/074807

§ 371 Date: Jun. 10, 2009

(30) Foreign Application Priority Data
Feb. 13, 2007 (JP) 2007-032019
Feb. 28, 2007 (JP) 2007-048704
Feb. 28, 2007 (JP) 2007-048705

(51) Int. Cl. H03H 9/15

(52) U.S. Cl. 333/187

(57) ABSTRACT

A piezoelectric resonator device includes a metal base through which at least two metal lead terminals are erected via an insulating material, a piezoelectric resonator plate that is placed on the metal lead terminals and is electrically connected to the metal lead terminals via an electroconductive resin adhesive, and a metal lid that hermetically covers the piezoelectric resonator plate placed on the metal lead terminals.

The electroconductive resin adhesive has flexibility of at least a pencil hardness of 4B. Also, an anticorrosive film is formed on the outer surface of the metal base and the metal lead terminals, and the electroconductive resin adhesive is used for the direct electrical connecting and mechanical joining of the ends of the piezoelectric resonator plate to the upper face of the anticorrosive film of the metal lead terminals inside the hermetic seal.

Alternatively, the piezoelectric resonator plate has a rectangular shape in plan view, and is placed on the metal lead terminals with the main face thereof facing in the same direction as the plane of the metal base. Wide nail-head parts on which the piezoelectric resonator plate is placed are formed at the end portions of the metal lead terminals inside the hermetic seal, and the piezoelectric resonator plate is attached at both ends of its long sides via the electroconductive resin adhesive in a state in which the middle parts of the short sides of the piezoelectric resonator plate are placed near the location of the center of gravity of the nail-head parts. The width of the piezoelectric resonator plate in its short side direction is set to not more than 2.8 times the width of the region of the nail-head part on the top portion thereof in the same direction that is joined with the electroconductive resin adhesive.

### TECHNICAL FIELD

The present invention relates to a piezoelectric resonator device such as a crystal resonator, and more particularly relates to the support structure of a piezoelectric resonator device having a sealed terminal structure in which metal lead terminals are integrally formed on a metal base with an insulating material interposed in between.

### BACKGROUND ART

Examples of piezoelectric resonator devices include crystal resonators, crystal filters, and crystal oscillators. Crystal resonators, for example, are widely used as sources of reference for frequency and time because of their outstanding resonance characteristics. With these piezoelectric resonator devices, a metal thin film electrode is formed on the surface of a crystal resonator plate (piezoelectric resonator plate), and this is hermetically sealed into a package including a metal base and a lid in order to protect the metal thin film electrode from the outside atmosphere.

With a conventional piezoelectric resonator device having a sealed terminal structure, a pair of metal lead terminals are erected on a metal base via glass or another such insulating material, and a pair of flat metal support members are attached facing each other on the inner side of the package of the metal lead terminals. A piezoelectric resonator plate is, for example, an AT cut crystal resonator plate with thickness-shear vibration, and excitation electrodes and take-off electrodes from these excitation electrodes are formed on the front and back faces thereof.

The piezoelectric resonator plate is placed on the supports and electro-mechanically connected by an electroconductive adhesive, and a metal lid is placed over the metal base and joined by resistance welding or another such means, resulting in a structure in which the inside of the package is hermetically sealed.

With the above-mentioned piezoelectric resonator device, however, the use of the support members increases the overall height of the piezoelectric resonator device, which runs contrary to the need for reducing the height on the electronic device side. Another problem is higher overall cost.

To solve the above problems, a piezoelectric resonator device has been proposed in Patent document 1 in which the support members are eliminated and part of the metal lead terminals is machined so that the piezoelectric resonator plate is directly supported by the metal lead terminals.

Patent document 1: JP 2001-160730A

### DISCLOSURE OF INVENTION

### Problem to be Solved by the Invention

With a piezoelectric resonator device such as that discussed in Patent Document 1, in which the support members are eliminated and part of the metal lead terminals is machined so that the piezoelectric resonator plate is directly supported by the metal lead terminals, impact resistance is not as good as with a support structure in which the support members are interposed.

The present invention was conceived in an effort to solve the above problems, and it is an object thereof to provide a piezoelectric resonator device with improved impact resistance.

### Means for Solving Problem

In order to solve the above problems, the piezoelectric resonator device of the present invention includes a metal base through which at least two metal lead terminals are erected via an insulating material, a piezoelectric resonator plate that is placed on the metal lead terminals and is electrically connected to the metal lead terminals via an electroconductive resin adhesive, and a metal lid that hermetically covers (hermetically seals) the piezoelectric resonator plate placed on the metal lead terminals, wherein the electroconductive resin adhesive has flexibility of at least a pencil hardness of 4B, an anticorrosive film is formed on the outer surface of the metal base and the metal lead terminals, and the electroconductive resin adhesive is used for the direct electrical connecting and mechanical joining of the ends of the piezoelectric resonator plate to the upper face of the anticorrosive film of the metal lead terminals hermetically sealed.

With the above constitution, because the device includes the metal base, the piezoelectric resonator plate, and the metal lid, and the electroconductive resin adhesive has flexibility of at least a pencil hardness of 4B, and an anticorrosive film is formed on the outer surface of the metal base and the metal lead terminals, and the electroconductive resin adhesive is used for the direct electrical connecting and mechanical joining of the ends of the piezoelectric resonator plate to the upper face of the anticorrosive film of the metal lead terminals hermetically sealed (on the inner side of the metal lead terminals), more reliable conduction can be ensured with the electrodes (excitation electrodes, etc.) of the piezoelectric resonator plate on the inner side of the metal lead terminals. As a result, the impact resistance of this piezoelectric resonator device can be increased while conduction performance is also improved.

In contrast, in Patent Document 1 above, impact resistance is inferior to that with a support structure in which support members are interposed, and it is essential to use a soft, silicone-based electroconductive resin adhesive. However, a problem encountered with a structure that features a silicone-based electroconductive resin adhesive was that a nickel or other such anticorrosive film formed on the outer surface of the metal base and the metal lead terminals was adversely affected by an oxide layer formed on the uppermost face of the anticorrosive film. That is, the effect of the oxide layer was to raise the conduction resistance at the junction interface between the silicone-based electroconductive resin adhesive and the metal lead terminals, which sometimes diminished the conduction performance of the piezoelectric resonator device. As a result, the electrical performance, such as the serial resonance resistance (CI value), of the piezoelectric resonator device may suffer. However, these problems can be solved with the piezoelectric resonator device according to the present invention as discussed above.

That is, with the present invention, even though the cushioning action is limited by the elimination of the supports, impact resistance can be improved since the piezoelectric resonator plate is attached on the inner side of the metal lead terminals via the electroconductive resin adhesive that has flexibility of at least a pencil hardness of 4B, and compared to prior art involving the use of supports and an electroconductive resin adhesive, an oxide layer formed on the uppermost part of the anticorrosive film will have no adverse effect even when the device is put under a high-temperature environment at some point after the joining of the piezoelectric resonator plate, such as during a reflow step, and this improves conduction performance at the junction interface between the joined portion on the inner side of the metal lead terminals and the electroconductive resin adhesive having flexibility of at least a pencil hardness of 4B (such as a modified epoxy-based adhesive).

Although conduction performance can be improved without adverse effect from an oxide layer even with an ordinary electroconductive resin adhesive (such as a modified epoxy-based adhesive), in a low-temperature environment the piezoelectric resonator plate tends to be subjected to shrinkage stress from the resin, and this may result in inferior characteristics such as variance in the frequency-temperature characteristics. With the present invention, however, this problem can be ameliorated even when using an electroconductive resin adhesive (such as a modified epoxy-based adhesive).

The result of the above is that it is possible to improve the electrical characteristics of the piezoelectric resonator device, such as its serial resonance resistance (CI value) or its frequency-temperature characteristics. In particular, the conduction performance between the piezoelectric resonator plate and the metal lead terminals hermetically sealed (the inner side of the metal lead terminals) can be improved with a less expensive structure and without any special machining of the ordinary metal lead terminals on which only an anticorrosive film is formed, which means that the present invention is extremely practical.

Also, in addition to the above constitution, a constitution may be such that wide nail-head parts on which a rectangular piezoelectric resonator plate is placed are formed on the inner side of the metal lead terminals, an electroconductive resin adhesive having flexibility of at least a pencil hardness of 4B is used for the direct electrical connecting and mechanical joining of the ends of the long sides of the piezoelectric resonator plate to the upper face of the anticorrosive film of the nail-head parts. With this constitution, placement of the piezoelectric resonator plate is stable when it is joined to the inner side of the metal lead terminals, the joint strength between the piezoelectric resonator plate and the nail-head parts is also stable, and there is less twisting of the short side portions of the piezoelectric resonator plate during impact. This prevents problems of the cracking of the piezoelectric resonator plate and the separation of the electroconductive resin adhesive from the nail-head parts of the metal lead terminals.

Also, to solve the above problems, the piezoelectric resonator device of the present invention includes a metal base through which at least two metal lead terminals are erected via an insulating material, a piezoelectric resonator plate that is placed on the metal lead terminals and on which are formed excitation electrodes that are electrically connected to the metal lead terminals via an electroconductive resin adhesive, and a metal lid that hermetically covers (hermetically seals) the piezoelectric resonator plate placed on the metal lead terminals, wherein the electroconductive resin adhesive has flexibility of at least a pencil hardness of 4B, an anticorrosive film is formed on the outer surface of the metal base and the metal lead terminals, the electroconductive resin adhesive is used for the direct electrical connecting and mechanical joining of the ends of the piezoelectric resonator plate to the upper face of the anticorrosive film of the metal lead terminals hermetically sealed (the inner side of the metal lead terminals), wide nail-head parts on which the piezoelectric resonator plate is placed are formed on the metal lead terminals hermetically sealed, a rough part with an average surface roughness of 0.2 to 2 μm is formed in at least the region of the nail-head part that is joined with the electroconductive resin adhesive, and the electroconductive resin adhesive is used for the direct electrical connecting and mechanical joining of the ends of the piezoelectric resonator plate to the rough parts of the nail-head parts.

Also, in addition to the above constitution, a rough part with a maximum surface roughness (the roughness measured by maximum height) of 6 to 30 μm may be formed in at least the region of the nail-head part that is joined with the electroconductive resin adhesive.

With the above constitution, because the device includes the metal base, the piezoelectric resonator plate, and the metal lid, and the electroconductive resin adhesive has flexibility of at least a pencil hardness of 4B, and an anticorrosive film is formed on the outer surface of the metal base and the metal lead terminals, and the electroconductive resin adhesive is used for the direct electrical connecting and mechanical joining of the ends of the piezoelectric resonator plate to the upper face of the anticorrosive film of the metal lead terminals hermetically sealed (on the inner side of the metal lead terminals), and wide nail-head parts on which the piezoelectric resonator plate is placed are formed on the metal lead terminals hermetically sealed, and a rough part with an average surface roughness of 0.2 to 2 μm is formed in at least the region of the nail-head part that is joined with the electroconductive resin adhesive, and the electroconductive resin adhesive is used for the direct electrical connecting and mechanical joining of the ends of the piezoelectric resonator plate to the rough parts of the nail-head parts, more reliable conduction can be ensured with the electrodes (excitation electrodes, etc.) of the piezoelectric resonator plate at the rough parts of the nail-head parts of the metal lead terminals. As a result, the impact resistance can be increased while conduction performance is also improved, which eliminates the increase in the serial resonance resistance of the piezoelectric resonator device, and an inexpensive piezoelectric resonator device with excellent electrical connectivity can be provided.

In contrast, with in the above-mentioned Patent Document 1, impact resistance is inferior compared to a support structure in which support members are interposed, and it is essential to use a soft, silicone-based electroconductive resin adhesive. However, a problem encountered with a structure that features a silicone-based electroconductive resin adhesive was that a nickel or other such anticorrosive film formed on the outer surface of the metal base and the metal lead terminals was adversely affected by an oxide layer formed on the uppermost face of the anticorrosive film. That is, the effect of the oxide layer was to raise the conduction resistance at the junction interface between the silicone-based electroconductive resin adhesive and the metal lead terminals, which sometimes diminished the conduction performance of the piezoelectric resonator device. As a result, the electrical performance, such as the serial resonance resistance (CI value), of the piezoelectric resonator device may suffer. However, these problems can be solved with the piezoelectric resonator device according to the present invention as discussed above.

That is, with the present invention, even though the cushioning action is limited by the elimination of the supports, since the piezoelectric resonator plate is attached to the nail-head parts via the electroconductive resin adhesive that has flexibility of at least a pencil hardness of 4B, impact resistance can be improved. And since a rough part with an average surface roughness of 0.2 to 2 μm is formed in at least the region of the nail-head part that is joined with the electroconductive resin adhesive, an anchoring effect is produced by combination with the electroconductive resin adhesive, and this raises the joint strength of the piezoelectric resonator plate and the nail head parts. Furthermore, this anchoring effect causes the metal filler contained in the electroconductive resin adhesive to work its way into the base material portion of the nail-head parts of the metal lead terminals, and this improves the conduction performance by increasing the contact surface area between the metal filler and the nail-head parts.

If the above-mentioned surface roughness is less than 0.2 μm, the above-mentioned anchoring effect will be too weak to obtain satisfactory conduction performance. On the other hand, it is impractical for the surface roughness to be greater than 2 μm, because the anticorrosive film will be formed in a poor state, and as a result oxidation of the nail-head parts and so forth will be more likely to occur.

Also, in addition to the above constitution, an electroconductive resin adhesive that contains a metal filler whose average particle size of the metal filler is from 3 to 6 μm may be used for the direct electrical connecting and mechanical joining of the ends of the piezoelectric resonator plate to the rough parts of the nail-head parts.

With the above constitution, in addition to the effects described above, when the average particle size of the metal filler is set to not more than the roughness of the above-mentioned rough parts, this will further enhance how the metal filler formed at not more than the roughness of the above-mentioned rough parts works its way into the rough parts of the nail-head parts of the metal lead terminals, and a more reliable conduction path can be ensured via the metal filler formed at less than the roughness of the above-mentioned rough parts. As a result, conduction performance is more stable and consistently higher.

Also, in addition to the above constitution, a silicone-based electroconductive resin adhesive or a modified epoxy-based electroconductive resin adhesive may be used as the electroconductive resin adhesive.

When the above constitution is employed, in addition to the effects discussed above, even though the cushioning action is limited by the elimination of the supports, since the piezoelectric resonator plate is attached to the nail-head parts via the above-mentioned high-flexibility silicone-based electroconductive resin adhesive or high-flexibility modified epoxy-based electroconductive resin adhesive, impact resistance can be increased.

Also, if the above-mentioned silicone-based electroconductive resin adhesive is joined to the rough parts of the nail-head parts, then even when the device is put under a high-temperature environment at some point after the joining of the piezoelectric resonator plate, such as during a reflow step, the interaction of the anticorrosive film and the silicone-based electroconductive resin adhesive reduces the likelihood of an adverse effect from an oxide layer formed on the uppermost face of the anticorrosive film. As a result, there is no longer a decrease in conduction performance at the junction interface between the nail-head parts and the silicone-based electroconductive resin adhesive, and there is less deterioration of the electrical performance, such as the serial resonance resistance (CI value), of the piezoelectric resonator device.

Also, when the above-mentioned modified epoxy-based electroconductive resin adhesive is used, compared to the use of the above-mentioned silicone-based electroconductive resin adhesive, even when the device is put under a high-temperature environment at some point after the joining of the piezoelectric resonator plate, such as during a reflow step, any oxide layer formed on the uppermost face of the anticorrosive film will have no adverse effect, and this improves the conduction performance at the junction interface between the nail-head parts and the modified epoxy-based electroconductive resin adhesive. As a result, the improvement in electrical performance, such as the serial resonance resistance (CI value), of the piezoelectric resonator device will be far greater. In addition, if the modified epoxy-based electroconductive resin adhesive is joined to the rough parts of the nail-head parts, this further enhances the electrical connecting and mechanical joining between the nail-head parts of the metal lead terminals and the electrodes (excitation electrodes, etc.) of the piezoelectric resonator plate.

Also, in order to solve the above problems, the piezoelectric resonator device of the present invention includes a metal base through which at least two metal lead terminals are erected via an insulating material, a piezoelectric resonator plate that is placed on the metal lead terminals and is electrically connected to the metal lead terminals via an electroconductive resin adhesive, and a metal lid that hermetically covers (hermetically seals) the piezoelectric resonator plate placed on the metal lead terminals, wherein the piezoelectric resonator plate has a rectangular shape in plan view and is placed on the metal lead terminals with the main face thereof facing in the same direction as the plane of the metal base, wide nail-head parts on which the piezoelectric resonator plate is placed are formed at the end portions of the metal lead terminals hermetically sealed (on the inner side of the metal lead terminals), the piezoelectric resonator plate is attached at both ends of its long sides via the electroconductive resin adhesive in a state in which the middle parts of the short sides of the piezoelectric resonator plate are placed near the location of the center of gravity of the nail-head parts, and the width of the piezoelectric resonator plate in its short side direction is set to not more than 2.8 times the width of the region of the nail-head parts on the top portion thereof in the same direction that is joined with the electroconductive resin adhesive.

In contrast, in Patent Document 1 above, impact resistance is inferior to that with a support structure in which support members are interposed, and problems of the cracking of the piezoelectric resonator plate and the separation of the electroconductive resin adhesive from the metal lead terminals are more pronounced. With a conventional piezoelectric resonator device, these problems can lead to diminished electrical characteristics of the piezoelectric resonator device, and in severe cases they can even prevent the piezoelectric resonator device from oscillating. However, these problems can be solved with the piezoelectric resonator device according to the present invention as discussed above.

That is, the present invention is a sealed terminal type of piezoelectric resonator device in which the metal base equipped with the metal lead terminals, which are hermetically sealed and therefore highly reliable, is covered and hermetically sealed with the metal lid, and eliminating the support members contributes greatly to both a shorter height and a lower cost. Furthermore, since wide nail-head parts on which the piezoelectric resonator plate is placed are formed at the end portions of the metal lead terminals, and the piezoelectric resonator plate is attached at both ends of its long sides via the electroconductive resin adhesive in a state in which the middle parts of the short sides of the piezoelectric resonator plate are placed near the location of the center of gravity of the nail-head parts, and the width of the piezoelectric resonator plate in its short side direction is set to not more than 2.8 times the width of the region of the nail-head parts on the top portion thereof in the same direction that is joined with the electroconductive resin adhesive, placement of the piezoelectric resonator plate is stable when it is joined to the nail-head parts. Also, because the short sides of the piezoelectric resonator plate are set to not more than 2.8 times the width of the region of the nail-head parts on the top portion thereof joined with the electroconductive resin adhesive, the joint strength between the piezoelectric resonator plate and the nail-head parts is also stable, and twisting of the short side portions of the piezoelectric resonator plate during impact is completely eradicated. This prevents problems of the cracking of the piezoelectric resonator plate and the separation of the electroconductive resin adhesive from the nail-head parts of the metal lead terminals, and also eliminates any decrease in electrical characteristics of the piezoelectric resonator device and prevents a stop of oscillation. In other words, this improves the impact resistance of the piezoelectric resonator device.

Also, in addition to the above constitution, the region of the nail-head part that is joined with the electroconductive resin adhesive may be formed over the entire upper face of the nail-head parts, and the width of the piezoelectric resonator plate in its short side direction may be set to not more than 2.8 times the width of the nail-head parts in the same direction.

In this case, in addition to the effects described above, since the region of the nail-head parts joined with the electroconductive resin adhesive is formed over the entire upper face of the nail-head parts, and the width of the piezoelectric resonator plate in its short side direction is set to not more than 2.8 times the width of the nail-head parts in the same direction, setting the region of joining with the electroconductive resin adhesive is extremely easy by specifying the shape of the upper part of the nail-head parts, and even if the electroconductive resin adhesive should be applied in an excessive amount, the electroconductive resin adhesive will work its way around to the lower side of the nail-head parts, so there will be no variance at all in the width or surface area of the region of joining with the electroconductive resin adhesive. Also, with the above structure of the nail-head parts, compared to a structure that makes use of supports, the support portions will not undergo bending deformation, so the position of the placement site in the height direction will be stable, and the amount in which the nail-head parts are coated with the electroconductive resin adhesive will also be stable. As discussed above, the dimensions of the region of the nail-head parts joined with the electroconductive resin adhesive relative to the short sides of the piezoelectric resonator plate can be specified extremely easily and reliably. In particular, with a structure in which the piezoelectric resonator plate is joined directly to the upper part of the metal lead terminals, it was difficult to specify the shape, width, etc., of the region joined with the electroconductive resin adhesive, but these can be specified extremely easily and reliably by combining a structure in which the electroconductive resin adhesive is formed over the entire upper face of the nail-head parts.

FIG. 14 shows the results of an impact resistance test on a crystal resonator (the piezoelectric resonator device in the present invention) with the sealed terminal structure shown in FIG. 11, in which the electroconductive resin adhesive was formed over the entire upper face of the nail-head parts, and the ratio of the width W of the short side of a crystal resonator plate (the piezoelectric resonator plate in the present invention) to the diameter d of the nail-head parts was varied from 1.6 to 3.4 times. In this test, a silicone resin-based electroconductive adhesive was used as the above-mentioned electroconductive resin adhesive to join the nail-head parts with the crystal resonator plate, 20 samples of the crystal resonator set to the above-mentioned W/d ratios were dropped three times from a height of 150 cm, and the samples were then checked to find the problem-free proportion of the resonators in which the serial resonance resistance (CI value) of the crystal resonator had risen, or there was frequency fluctuation, or oscillation had ceased. As is clear from these results, when the W/d ratio was between 1.6 and 2.8 times, the problem-free proportion was 100%, whereas when the W/d ratio was 3 times, this proportion dropped to 90%, and when the W/d ratio was 3.2 times, this proportion dropped to 80%, and when the W/d ratio was 3.4 times, this proportion dropped to 60%. This revealed that excellent impact resistance was obtained for samples in which the width W in the short side direction of the crystal resonator plate was set to within 2.8 times the width d of the nail-head parts in the same direction.

Also, with the above constitution, a silicone-based electroconductive resin adhesive may be used for electrical connecting and mechanical joining of the ends of the long sides of the piezoelectric resonator plate to the nail-head parts in a state in which an anticorrosive film (such as nickel plating) has been formed on at least the outer surface of the metal base and the two metal lead terminals, and at least one of silver plating and gold plating has been formed on at least the surface of the nail-head parts at the upper face of the anticorrosive film.

With the above constitution, in addition to the effects described above, even though the cushioning action is limited by the elimination of the supports, since the piezoelectric resonator plate is attached to the nail-head parts via the highly flexible silicone-based electroconductive resin adhesive, impact resistance can be improved. When silver or gold plating is formed on top of the anticorrosive film (such as nickel plating), a passivation film formed on top of the anticorrosive film by the interaction of the silicone-based electroconductive resin adhesive with the anticorrosive film will tend not to have an adverse effect even when the device is put under a high-temperature environment at some point after the joining of the piezoelectric resonator plate, such as during a reflow step. As a result, there is no longer a decrease in conduction performance at the junction interface between the nail-head parts and the silicone-based electroconductive resin adhesive, and there is less deterioration of the electrical performance, such as the serial resonance resistance (CI value), of the piezoelectric resonator device.

Also, with the above constitution, the electroconductive resin adhesive may have flexibility of at least a pencil hardness of 4B, and an anticorrosive film may be formed at least on the outer surface of the metal base and the two metal lead terminals, and the electroconductive resin adhesive may be used for the electrical connecting and mechanical joining of the ends of the long sides of the piezoelectric resonator plate to the nail-head parts at the upper face of the anticorrosive film.

With this constitution, in addition to the effects described above, even though the cushioning action is limited by the elimination of the supports, impact resistance can be improved because the piezoelectric resonator plate is attached to the nail-head parts via an electroconductive resin adhesive having flexibility of at least a pencil hardness of 4B. Also, when the above-mentioned electroconductive resin adhesive is used, a passivation film formed on top of the anticorrosive film will have no adverse effect even when the device is put under a high-temperature environment at some point after the joining of the piezoelectric resonator plate, such as during a reflow step, and conduction performance will be improved at the junction interface between the nail-head parts and the electroconductive resin adhesive. That is, no special machining is required for an ordinary lead terminal on which only an anticorrosive film is formed, so conduction performance can be improved between the nail-head parts and the piezoelectric resonator plate, and the electrical performance, such as the serial resonance resistance (CI value), of the piezoelectric resonator device, can be improved with a less expensive structure.

Also, with the above constitution, the surface of the nail-head parts may be roughened, or at least one of holes, grooves, and slits may be formed on the upper faces of the nail-head parts.

Employing this constitution improves the junction interface between the nail-head parts and the electroconductive resin adhesive, and increases the electro-mechanical joint strength of the electroconductive resin adhesive between the piezoelectric resonator plate and the nail-head parts. Furthermore, when holes, grooves, or slits are formed in the upper faces of the nail-head parts, this allows the electroconductive resin adhesive to puddle and reduces its out-flow, so the coating amount of the electroconductive resin adhesive is stabilized, which not only stabilizes the electromechanical joint strength of the electroconductive resin adhesive, but also eliminates shorting with the metal portion of the metal base.

### EFFECTS OF THE INVENTION

As discussed above, impact resistance can be improved with the piezoelectric resonator device according to the present invention.

### BRIEF DESCRIPTION OF DRAWINGS

FIG. 1 is a simplified cross-sectional view of a crystal resonator according to Example 1;

FIG. 2 is a simplified plan view of the metal base on which the piezoelectric resonator plate is placed prior to covering with the lid in FIG. 1;

FIG. 3 is a simplified plan view of the metal base prior to putting the piezoelectric resonator plate in place in FIG. 2;

FIG. 4 is a simplified cross-sectional view of a crystal resonator according to another example of Example 1;

FIG. 5 is a simplified plan view of the metal base prior to putting the piezoelectric resonator plate in place in FIG. 4;

FIG. 6 is a simplified cross-sectional view of a crystal resonator according to another example of Example 1;

FIG. 7 is a simplified cross-sectional view of a crystal resonator according to another example of Example 1;

FIG. 8 is a simplified cross-sectional view of a crystal resonator according to another example of Example 1;

FIG. 9 is a simplified cross-sectional view of a crystal resonator according to another example of Example 1;

FIG. 10 is a simplified plan view of the metal base prior to putting the piezoelectric resonator plate in place, according to Example 2;

FIG. 11 is a simplified cross-sectional view of a crystal resonator according to Example 3;

FIG. 12 is a simplified plan view of the metal base on which the piezoelectric resonator plate is placed prior to covering with the lid in FIG. 11;

FIG. 13 is a simplified plan view of the metal base prior to putting the piezoelectric resonator plate in place in FIG. 12; and

FIG. 14 is a graph of the results of an impact resistance test conducted for the piezoelectric resonator plate according to Example 3.

### DESCRIPTION OF REFERENCE NUMERALS

1 base
10 base main body
11, 12 lead terminal
2 piezoelectric resonator plate
3 lid

### BEST MODE FOR CARRYING OUT THE INVENTION

### Example 1

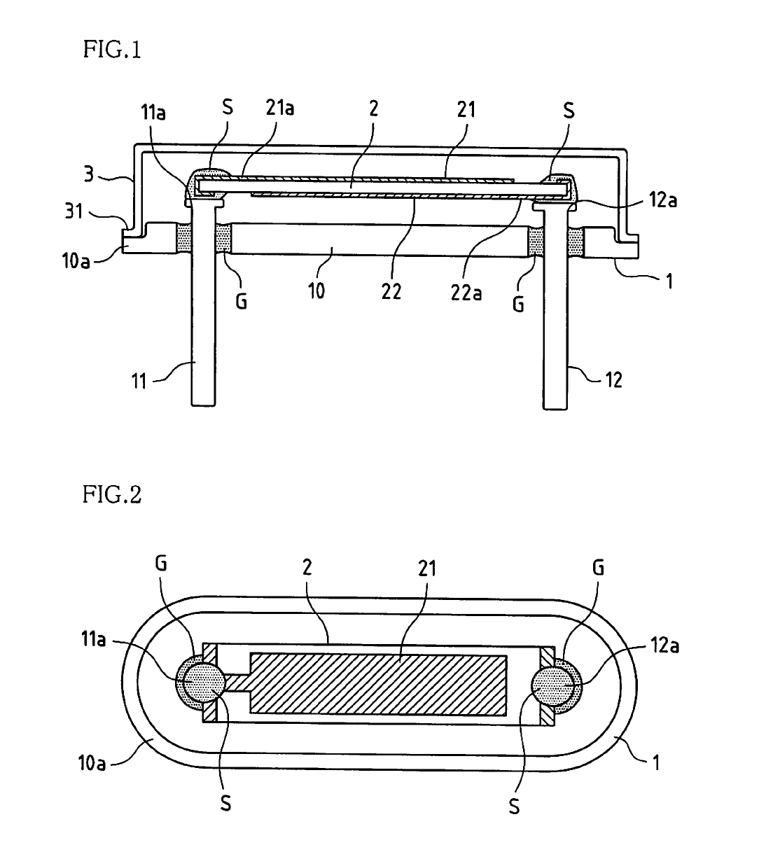

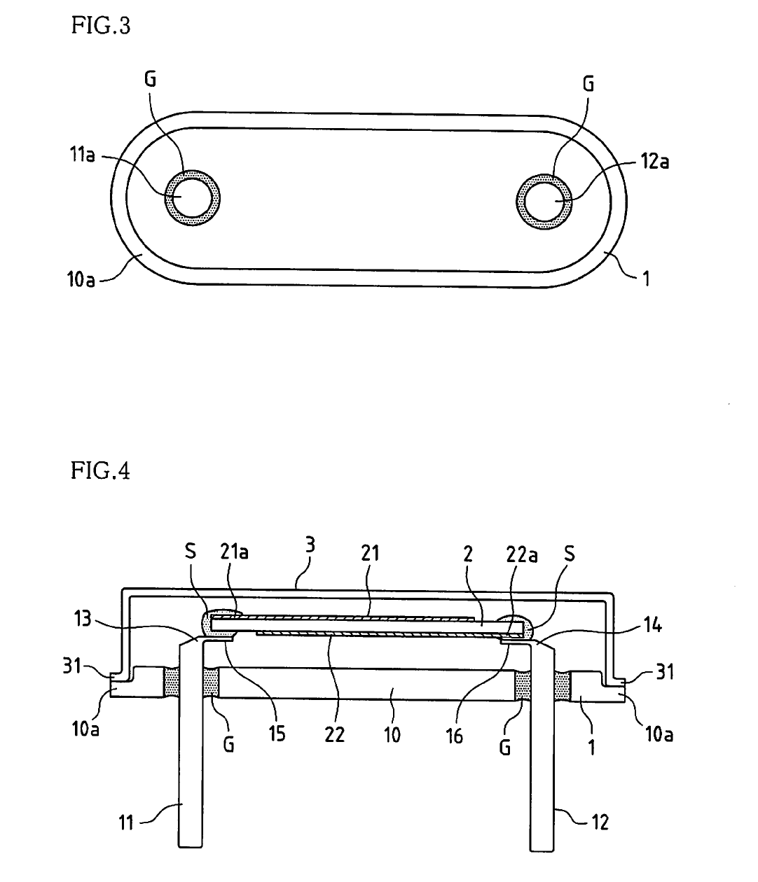

Next, embodiments (examples) of the present invention will be described through reference to the drawings, using a crystal resonator as an example. FIG. 1 is a simplified cross-sectional view of a crystal resonator according to Example 1 of the present invention, FIG. 2 is a simplified plan view of a base prior to covering with the lid in FIG. 1, and FIG. 3 is a simplified plan view of the base prior to putting the piezoelectric resonator plate in place in FIG. 2.

A piezoelectric resonator plate 2 includes an AT cut crystal resonator plate, and is worked into a rectangular shape in plan view, consisting of short and long sides. The front and back faces (main faces) thereof are provided with excitation electrodes 21 and 22 and take-off electrodes 21a and 22a by vacuum vapor deposition or another such means. For electrical connection (discussed below) to be carried out reliably, the take-off electrodes 21a and 22a are each wrapped around to the other main face. As to the electrode materials, a laminated structure including one or more main electrode layers whose main component is silver or gold is formed on top of a base electrode layer of chromium or nickel. With the piezoelectric resonator plate 2 according to Example 1, the length of the long sides thereof in plan view is set to 5.0 mm, and the length of the short sides thereof in plan view is set to between 1.5 and 2.5 mm.

A base 1 (the metal base in the present invention) has an oval cylinder shape that is short in height overall, and metal lead terminals 11 and 12 are erected passing through a base main body 10 that mainly includes a metal shell. The metal lead terminals 11 and 12 are erected passing through insulating glass G that is packed into part of the base main body 10. The metal lead terminals 11 and 12 are erected opposite each other on the base main body 10, and the metal lead terminals 11 and 12 are electrically independent of one another. A peripheral flange 10a is integrally provided to the lower peripheral edge portion of the base main body 10. A peripheral projection (not shown) is integrally formed on the flange 10a.

The metal lead terminals 11 and 12 are in the form of a slender cylinder composed of Kovar or the like, and nail-head parts 11a and 12a that are wide and whose upper part is flat and substantially circular in plan view are formed at the ends on the inner side of the upper part of the base 1. These nail-head parts 11a and 12a are formed by stamping or another process that takes advantage of the ductility of metal. As an example of the specific dimensions of the metal lead terminals 11 and 12, the diameter of the metal lead terminals 11 and 12 is about 0.32 to 0.45 mm, while the width d of the nail-head parts 11a and 12a is about 0.7 to 0.9 mm. The term “inner” as used above means the interior space formed by the joining of the base 1 and a lid 3 (see below), which is hermetically sealed to include the piezoelectric resonator plate 2 placed on the base 1. “On the inner side” means a portion of the metal lead terminals 11 and 12 erected passing through the base 1 and located inside the hermetically-sealed interior space.

Although not shown in the drawings, the metal portions exposed on the surface of the base 1 and the metal lead terminals 11 and 12 are given an inexpensive and practical nickel plating film to prevent corrosion. In particular, in Example 1, a nickel electroplating film is formed in a thickness of about 4 to 6 μm by an electrolytic plating method, and an electroless nickel plating film is formed over this in a thickness of about 2 to 5 μm by an electroless plating method. A nickel electroplating film has a higher melting point than an electroless nickel plating film, and an anticorrosive function before and after firing can be obtained by forming this film prior to the firing of the insulating glass G. The electroless nickel plating film is formed as a film with more uniform quality than the nickel electroplating film, so not only does it improve wettability with solder and the like, but it results in an amorphous structure in which phosphorus, boron, and so forth originating in a reducing agent are co-deposited on the uppermost surface, and this yields an anticorrosive film that is hard and has better corrosion resistance. In other words, the electroless nickel plating film serves as an anticorrosive film on the uppermost surface of the base 1 and the metal lead terminals 11 and 12, providing high reliability and extremely good practicality despite a low cost, but a problem is that conduction resistance at the junction interface with the electroconductive resin adhesive S tends to be increased by the adverse effect of an oxidation layer. However, in Example 1, these problems can be ameliorated by combining with the modified epoxy-based electroconductive resin adhesive S discussed below.

Also, erecting the metal lead terminals 11 and 12 passing through the base main body 10 via the insulating glass G causes the insulating glass G to form a meniscus at the joint with the metal lead terminals 11 and 12, as shown in FIG. 1. When the insulating glass G forms this meniscus, the positions where the metal lead terminals 11 and 12 are erected on the base main body 10 can be centered, allowing the metal lead terminals 11 and 12 to be formed at the desired locations on the base main body 10.

The metal lid 3 has an oval cylinder shape and is open at the bottom, and this open portion has a flange 31 corresponding to the flange 10a of the base. The flange 31 of this lid 3 is resistance welded to the base 1 (more specifically, to the flange 10a), which joins it to the base 1 and forms a packaged crystal resonator. Resistance welding the lid 3 to the base 1 hermetically seals the interior space of the package. The “inner side” of the metal lead terminals 11 and 12 refers to the portions of the metal lead terminals 11 and 12 on the inside of the hermetic seal.

Prior to the direct electrical connecting and mechanical joining of the piezoelectric resonator plate 2 with the nail-head parts 11a and 12a on the inner side of the metal lead terminals 11 and 12 via the electroconductive resin adhesive S, the outer surface of the base 1 is treated with acid.

More specifically, in Example 1 the acid treatment of the nickel plating film is accomplished by washing with dilute hydrochloric acid, for example. The oxidation layer on the upper face of the electroless nickel plating film (anticorrosive film) is removed or only remains in places by the washing on the outer surface of the base 1 (the metal lead terminals 11 and 12 and the base main body 10) washed with this dilute hydrochloric acid.

After acid washing, the metal surface has either had the oxidation film removed, or the oxidation film is only left in places, so this surface is in a state of extremely high activity. When the base 1 is left in this state, an oxidation film of the metal surface will be formed again on the base 1, which has the adverse effect of increasing the thickness thereof. Therefore, before there is an increase in thickness to a thickness that is adversely affected by the oxidation film from the base 1 in this state, the piezoelectric resonator plate 2 is placed so that the middle parts of its short sides are placed near the center of gravity of the nail-head parts 11a and 12a on the inner side of the metal lead terminals 11 and 12, the nail-head parts 11a and 12a and the ends of the long sides of the piezoelectric resonator plate 2 are directly electro-mechanically joined via the modified epoxy-based electroconductive resin adhesive S having flexibility greater than a pencil hardness of 4B, and the piezoelectric resonator plate 2 is attached (placed) on the nail-head parts 11a and 12a. Here, the entire upper surface of the nail-head parts 11a and 12a is formed as the joining region with the electroconductive resin adhesive S. In this Example 1, the distance between the centers of gravity of the nail-head parts 11a and 12a is set to 4.8 mm.

As discussed above, the piezoelectric resonator device of Example 1 includes the base 1, the piezoelectric resonator plate 2, and the lid 3, an anticorrosive film (electroless nickel plating film) is formed on the outer surface of the metal lead terminals 11 and 12 and the base 1, an oxidation layer of the anticorrosive film is formed on the upper face of this anticorrosive film, and an electroconductive resin adhesive S with flexibility greater than a pencil hardness of 4B is used for the direct electrical connecting and mechanical joining of the piezoelectric resonator plate 2 to the upper face of the oxidation layer of the anticorrosive film, on the inner side of the metal lead terminals 11 and 12, in a state in which the oxidation layer of at least the portion coated with the electroconductive resin adhesive S is thinner than the oxidation layer in the other region, or a state in which the oxidation film is present only in places.

Also, a urethane-modified epoxy-based electroconductive resin adhesive (such as one from the XA-471B-3 series made by Fujikura Kasei), for example, was used as the modified epoxy-based electroconductive resin adhesive S with flexibility greater than a pencil hardness of 4B.

Also, in Example 1, a modified epoxy-based electroconductive resin adhesive with flexibility greater than a pencil hardness of 4B is used as the electroconductive resin adhesive S, but the present invention is not limited to this, and the electroconductive resin adhesive S may be any type that at least has flexibility of a pencil hardness of 4B. For instance, it may be a silicone-based electroconductive resin adhesive with a pencil hardness of 6B, which is more flexible than one with a pencil hardness of 4B. It may also be a modified epoxy-based electroconductive resin adhesive with a pencil hardness of 4B. The result of forming in this way is that the piezoelectric resonator plate 2 and the metal lead terminals 11 and 12 can be joined without being adversely affected by the oxidation layer on the upper face of the electroless nickel plating film (anticorrosive film). In particular, adhesive strength is increased for a thin oxidation film on the resin part of the electroconductive resin adhesive S, or for an oxidation film that is present only in places. As a result, there is a higher probability of contact between the metal filler of the electroconductive resin adhesive S and the base material portion of the metal lead terminals 11 and 12, and not only does conduction performance improve, but the mechanical joint strength also increases.

The metal filler contained in the electroconductive resin adhesive S preferably is in the form of flakes whose main component is silver or the like, and the average particle size of the metal filler is preferably from 3 to 6 μm. The result of this is that the there is a higher probability that the flakes of metal filler contained in the electroconductive resin adhesive S will come into contact with the nail-head parts 11a and 12a of the metal lead terminals 11 and 12, and conduction performance is more stably and reliably enhanced.

After placement of the piezoelectric resonator plate 2 on the base 1 using the above constitution, annealing and other such necessary treatments are performed. After this, the base 1 is covered with the lid 3, and although not depicted, welding electrodes are brought into contact with the flanges 10a and 31 and pressure is applied to them while current is allowed to flow and resistance welding performed, which completes the hermetic sealing of the package consisting of the base 1 and the lid 3.

The crystal resonator according to Example 1 of the present invention includes the metal base 1, through which the metal lead terminals 11 and 12 are erected via the insulating glass G, the rectangular piezoelectric resonator plate 2, which is in the same direction as the plane of the metal base 1 and which is placed on the metal lead terminals 11 and 12 and on which are formed the excitation electrodes 21 and 22 that are electrically connected via the electroconductive resin adhesive S, and the metal lid 3 that hermetically covers (hermetically seals) the piezoelectric resonator plate 2 placed on the metal lead terminals 11 and 12; the electroconductive resin adhesive S has at least flexibility of a pencil hardness of 4B. An electroless nickel plating film (anticorrosive film) is formed on the outer surface of the metal base 1 and the metal lead terminals 11 and 12, the wide nail-head parts 11a and 12a on which the piezoelectric resonator plate 2 is placed are formed on the inner side of the metal lead terminals 11 and 12, and the electroconductive resin adhesive S is used for the direct electrical connecting and mechanical joining of the ends of the long sides of the piezoelectric resonator plate 2 to the upper faces of the nail-head parts 11a and 12a (electroless nickel plating film on the inner side) of the metal lead terminals 11 and 12. Therefore, better conduction can be ensured with the electrodes (such as the excitation electrodes 21 and 22) of the piezoelectric resonator plate 2 on the inner side of the metal lead terminals 11 and 12. As a result, impact resistance performance is improved while conduction performance is also enhanced, thus eliminating the increase in the serial resonance resistance (CI value) of the crystal resonator, and affording an inexpensive crystal resonator with excellent electrical connectivity.

In contrast, in Patent Document 1 above, impact resistance is inferior to that with a support structure in which support members are interposed, and it is essential to use a soft, silicone-based electroconductive resin adhesive. However, a problem encountered with the conventional constitution of Patent Document 1 was that when a silicone-based electroconductive resin adhesive was used, the nickel or other such anticorrosive film formed on the outer surface of the metal base and the metal lead terminals was adversely affected by an oxidation layer formed on the uppermost face of the anticorrosive film. That is, the effect of the oxidation layer was to raise the conduction resistance at the junction interface between the silicone-based electroconductive resin adhesive and the metal lead terminals, which sometimes diminished the conduction performance of the piezoelectric resonator device. As a result, the electrical performance, such as the serial resonance resistance (CI value), of the piezoelectric resonator device may suffer. However, these problems can be solved with the crystal resonator according to Example 1 as discussed above.

Even though the cushioning action is limited by the elimination of the supports with the above constitution, impact resistance can be improved since the piezoelectric resonator plate 2 is attached to the nail-head parts 11a and 12a via an electroconductive resin adhesive with flexibility at least of a pencil hardness of 4B (in this embodiment, the modified epoxy-based electroconductive resin adhesive S with flexibility greater than a pencil hardness of 4B), and compared to prior art involving the use of supports and a silicone-based electroconductive resin adhesive, an oxidation layer with an amorphous structure formed on the uppermost face of the electroless nickel plating film (anticorrosive film) will have no adverse effect even when the device is put under a high-temperature environment at some point after the joining of the piezoelectric resonator plate 2, such as during a reflow step, and this improves conduction performance at the junction interface between the nail-head parts 11a and 12a and the electroconductive resin adhesive S. In particular, in Example 1, the wide nail-head parts 11a and 12a on which the piezoelectric resonator plate is placed are formed on the inner side of the metal lead terminals 11 and 12, and the modified epoxy-based electroconductive resin adhesive S with flexibility greater than a pencil hardness of 4B is used for the direct electrical connecting and mechanical joining of the ends of the long sides of the piezoelectric resonator plate 2 to the nail-head parts 11a and 12a on the upper face of the electroless nickel plating film (anticorrosive film) of the nail-head parts 11a and 12a, so placement of the piezoelectric resonator plate 2 is stable when it is joined to the inner side of the metal lead terminals 11 and 12, the joint strength between the piezoelectric resonator plate 2 and the nail-head parts 11a and 12a is increased and stabilized, and there is less twisting of the short side portions of the piezoelectric resonator plate 2 upon impact.

Even with an ordinary electroconductive resin adhesive (such as a modified epoxy-based adhesive), conduction performance can be improved without any adverse effect from an oxidation layer, but in a low-temperature environment the piezoelectric resonator plate 2 tends to be subjected to shrinkage stress from the resin, and this may result in inferior characteristics such as variance in the frequency-temperature characteristics. With Example 1, however, this problem can be ameliorated even when using the electroconductive resin adhesive S.

With Example 1, an anticorrosive film is formed on the outer surface of the base 1 and the metal lead terminals 11 and 12, an oxidation layer of the anticorrosive film is formed on the upper face of this anticorrosive film, and an electroconductive resin adhesive S with flexibility greater than a pencil hardness of 4B is used for the direct electrical connecting and mechanical joining of the piezoelectric resonator plate 2 to the upper face of the oxidation layer of the anticorrosive film, on the inner side of the metal lead terminals 11 and 12, in a state in which the oxidation layer of at least the portion coated with the electroconductive resin adhesive S is thinner than the oxidation layer in the other region, or a state in which the oxidation film is present only in places, so better conduction can be ensured with the electrodes of the piezoelectric resonator plate 2 at the portions coated with the electroconductive resin adhesive S on the inner side of the metal lead terminals 11 and 12. As a result, impact resistance performance is improved while conduction performance is also enhanced, thus eliminating the increase in the serial resonance resistance of the piezoelectric resonator device, and affording an inexpensive piezoelectric resonator device with excellent electrical connectivity.

In other words, since an electroconductive resin adhesive S with flexibility greater than a pencil hardness of 4B is used for the direct electrical connecting and mechanical joining of the piezoelectric resonator plate 2 to the upper face of the oxidation layer of the anticorrosive film, on the inner side of the metal lead terminals 11 and 12, in a state in which the oxidation layer of at least the portion coated with the electroconductive resin adhesive S is thinner than the oxidation layer in the other region, or a state in which the oxidation film is present only in places, the adhesive strength of the resin component of the electroconductive resin adhesive S is increased for the thinner oxidation film or the oxidation film present only in places. As a result, there is a higher probability of contact between the metal filler and the base material portion of the metal lead terminals 11 and 12, and conduction performance is improved.

Also, in Example 1, the method for manufacturing this piezoelectric resonator device includes a step of forming an anticorrosive film on the outer surface of the base 1 and the metal lead terminals 11 and 12, a step of washing the outer surface of the base 1 and the metal lead terminals 11 and 12 with dilute hydrochloric acid and then coating the inner side of the metal lead terminals 11 and 12 with an electroconductive resin adhesive S with flexibility greater than a pencil hardness of 4B, and a step of placing the ends of the piezoelectric resonator plate 2 on the inner side of the metal lead terminals 11 and 12 coated with the electroconductive resin adhesive S, and directly electro-mechanically joining the piezoelectric resonator plate 2 with the inner side of the metal lead terminals 11 and 12 via the electroconductive resin adhesive S, so the outer surface of the base 1 and the metal lead terminals 11 and 12 washed with dilute hydrochloric acid is in a state in which the oxidation layer on the upper face of the anticorrosive film has been removed or only remains in places.

Accordingly, in Example 1, the piezoelectric resonator plate 2 and the metal lead terminals 11 and 12 are joined in a state of being adversely unaffected by the oxidation layer formed on the upper face of the anticorrosive film. In particular, the adhesive strength of the resin component of the electroconductive resin adhesive S is increased for the thinner oxidation film or the oxidation film present only in places. As a result, there is a higher probability of contact between the metal filler and the base material portion of the metal lead terminals 11 and 12, and conduction performance is improved.

After this, at least on the other outer surface of the base 1 or the metal lead terminals 11 and 12 not coated with the electroconductive resin adhesive S, and on the inner side of the metal lead terminals 11 and 12, the thickness of the oxidation layer formed on the upper face of the anticorrosive film increases, so its function of preventing corrosion is enhanced.

Because of the above, in Example 1, it is possible to improve the electrical characteristics of the crystal resonator, such as its serial resonance resistance (CI value) or its frequency-temperature characteristics. In particular, the conduction performance between the piezoelectric resonator plate and the metal lead terminals hermetically sealed (the inner side of the metal lead terminals) can be improved with a less expensive structure and without any special machining of the ordinary metal lead terminals on which only an anticorrosive film is formed, which means that the present invention is extremely practical.

Also, with Example 1, wide nail-head parts 11a and 12a on which the rectangular piezoelectric resonator plate 2 is placed are formed on the inner side of the metal lead terminals 11 and 12, an electroconductive resin adhesive having flexibility of at least a pencil hardness of 4B (in Example 1, the modified epoxy-based electroconductive resin adhesive S) is used for the direct electrical connecting and mechanical joining of the ends of the long sides of the piezoelectric resonator plate 2 to the upper face of the anticorrosive film of the nail-head parts 11a and 12a. With this constitution, placement of the piezoelectric resonator plate 2 is stable when it is joined to the inner side of the metal lead terminals 11 and 12, the joint strength between the piezoelectric resonator plate 2 and the nail-head parts 11a and 12a is also stable, and there is less twisting of the short side portions of the piezoelectric resonator plate 2 during impact. This prevents problems of the cracking of the piezoelectric resonator plate 2 and the separation of the electroconductive resin adhesive S from the nail-head parts 11a and 12a of the metal lead terminals 11 and 12.

In Example 1 above, the electroconductive resin adhesive S having flexibility of at least a pencil hardness of 4B is used, and this is a material with good DLD characteristics and impact resistance, which would otherwise be lost because of the elimination of the supports used in prior art, and is a material that also improves conduction characteristics when the constitution of Example 1 is included. Usually, DLD characteristics and impact resistance are mutually exclusive from conduction characteristics, and only one or the other can be achieved with an ordinary electroconductive adhesive. However, the electroconductive resin adhesive S according to Example 1 makes it possible to achieve good impact resistance, DLD characteristics, and conduction characteristics.

Also, in Example 1, washing with dilute hydrochloric acid is performed prior to the direct electrical connecting and mechanical joining of the piezoelectric resonator plate 2 and the nail-head parts 11a and 12a on the inner side of the metal lead terminals 11 and 12 via the electroconductive resin adhesive S, the result being that the oxidation layer formed on the upper face of the electroless nickel plating film (anticorrosive film) of the upper face portion of the nail-head parts 11a and 12a, which is at least the portion coated with the electroconductive resin adhesive S, is in a state of being thinner than the oxidation layer in the other region, or the oxidation film is present only in places. However, the oxidation layer formed on the upper face of the electroless nickel plating film (anticorrosive film) can also be removed, and the same effect can be obtained, also by grinding at least the portion coated with the electroconductive resin adhesive on the inner side of the metal lead terminals, such as the upper face part of the nail-head parts 11a and 12a, prior to the direct electrical connecting and mechanical joining of the piezoelectric resonator plate 2 and the nail-head parts 11a and 12a on the inner side of the metal lead terminals 11 and 12 via the electroconductive resin adhesive S. Furthermore, an anchoring effect is produced by the electroconductive resin adhesive in this ground-away region, which not only improves the electrical connectivity, but also increases the mechanical joint strength.

In Example 1, the length of the long sides of the piezoelectric resonator plate 2 in plan view is set to 5.0 mm, the length of the short sides is set to between 1.5 and 2.5 mm, and the distance between the centers of gravity of the nail-head parts 11a and 12a is set to 4.8 mm, but other dimensions are also possible, and may be set as desired, as long as the length of the long sides in plan view of the piezoelectric resonator plate 2 is greater than the distance between the centers of gravity of the nail-head parts 11a and 12a. Therefore, for example, the length of the long sides in plan view of the piezoelectric resonator plate 2 may be set to 3.0 mm, and the distance between the centers of gravity of the nail-head parts 11a and 12a may be set to 2.8 mm.

Variations on Example 1

In Example 1, the nail-head parts 11a and 12a are formed on the inner side of the metal lead terminals 11 and 12, but the nail-head parts 11a and 12a may not be formed and the piezoelectric resonator plate 2 may be directly joined to the inner side of the metal lead terminals 11 and 12, rather than being formed.

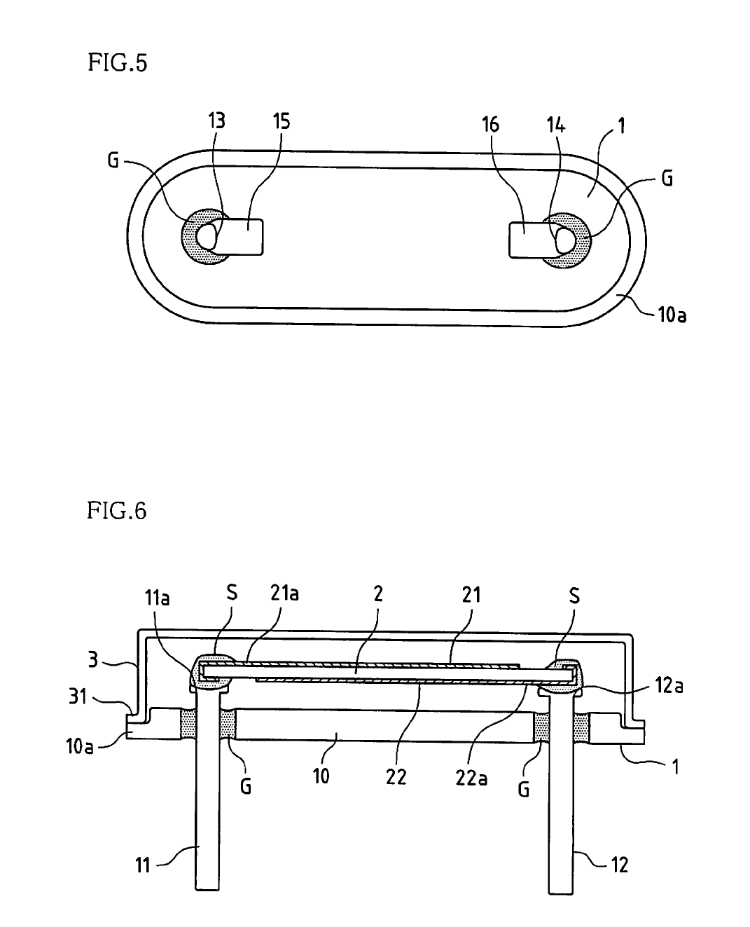

Also, as shown in FIGS. 4 and 5, the present invention can be applied to a constitution of the metal lead terminals 11 and 12 in which connected parts 13 and 14, which extend toward each other and are formed such that they progressively decrease in thickness and progressively increase in width, and placement parts 15 and 16, which are flat and are wider than the metal lead terminals 11 and 12 and are formed at the ends of the connected parts 13 and 14, are formed on the inner side of the metal lead terminals 11 and 12. In other words, the electroconductive resin adhesive S having flexibility of at least a pencil hardness of 4B is used for the direct electrical connecting and mechanical joining of the ends of the long sides of the piezoelectric resonator plate 2 to the flat placement parts 15 and 16. With this constitution, the placement parts 15 and 16 are disposed on the inside portion where the metal lead terminals 11a and 12a are erected, so not only can this be applied to a smaller piezoelectric resonator plate 2, but less stress will be transmitted to the connected parts 13 and 14, and the cushioning function can be enhanced.

Also, a laminated plating layer of silver flash plating, gold plating, or a combination of these may be formed over the nickel plating layer on at least the surface of the nail-head parts 11a and 12a, which reduces the adverse effect of the oxidation layer formed on the electroless nickel plating film or other anticorrosive film, and improves conduction performance at the junction interface with the electroconductive resin adhesive S.

Also, the upper faces of the nail-head parts 11a and 12a are flat here, but are not necessarily so, and as shown in FIG. 6, the upper faces of the nail-head parts 11a and 12a may be curved in a concave shape. Here again, this allows the electroconductive resin adhesive S to puddle and reduces its out-flow, so the coating amount of the electroconductive resin S adhesive is stabilized, which not only stabilizes the electromechanical joint strength of the electroconductive resin adhesive S, but also eliminates shorting with the metal portion of the metal base 1.

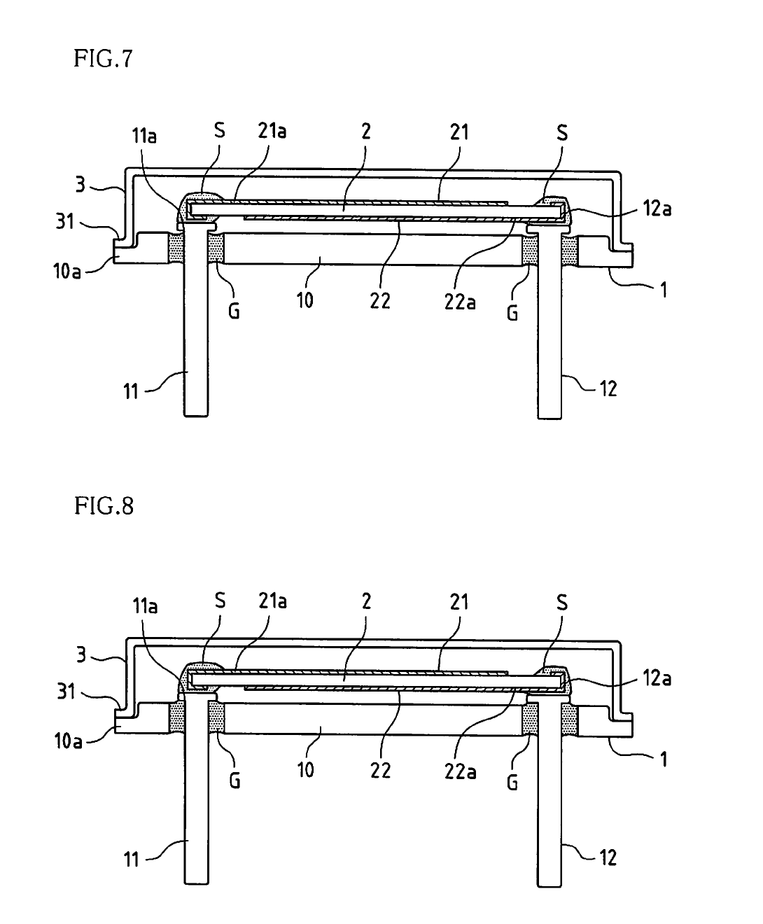

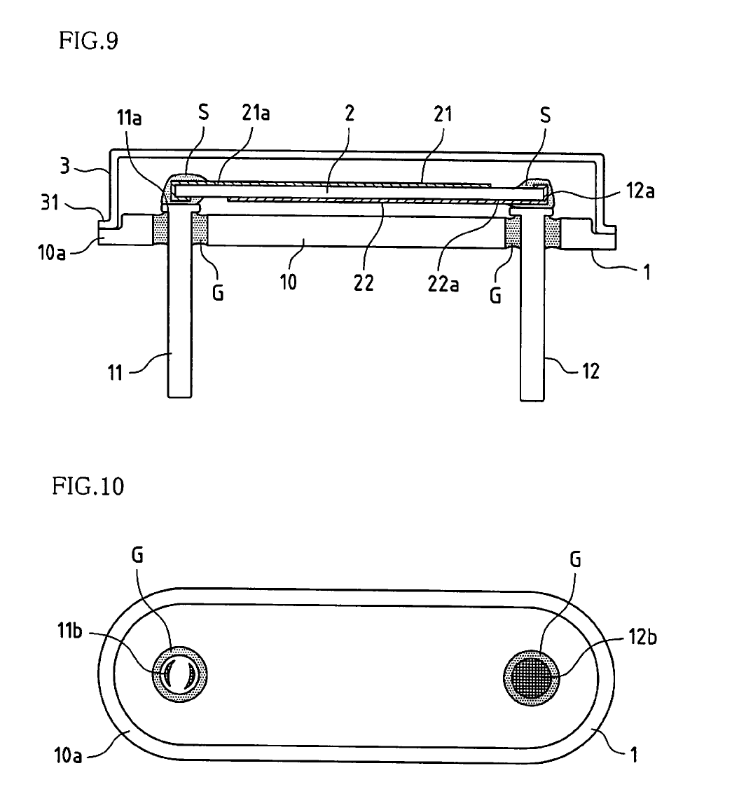

Also, Example 1, the metal lead terminals 11 and 12 are erected on the base 1 passing through the base 1 via the insulating glass G, but the manner in which the metal lead terminals 11 and 12 are erected passing through the base 1 is not limited to this, and the metal lead terminals 11 and 12 may instead be erected passing through the base 1 as shown in FIGS. 7, 8, and 9. In the configuration shown in FIGS. 7, 8, and 9, the inner side of the metal lead terminals 11 and 12 (the portions of the metal lead terminals 11 and 12 located within the hermetically sealed space) is only the nail-head parts 11a and 12a formed at the ends of the metal lead terminals 11 and 12, and this allows the crystal resonator to be made shorter than the erection configuration of the metal lead terminals 11 and 12 shown in FIG. 1. Furthermore, with the configuration shown in FIG. 7, where the insulating glass G is joined with the metal lead terminals 11 and 12 is the location where the nail-head parts 11a and 12a are disposed on the metal lead terminals 11 and 12 (the base of the nail-head parts 11a and 12a), and the insulating glass G forms a meniscus at these places. With the configuration shown in FIG. 8, where the insulating glass G is joined with the metal lead terminals 11 and 12 is the lower end position of the side faces of the nail-head parts 11a and 12a, and the insulating glass G forms a meniscus at these places. With the configuration shown in FIG. 9, where the insulating glass G is joined with the metal lead terminals 11 and 12 is near the center of the bottom faces of the nail-head parts 11a and 12a, and the insulating glass G forms a meniscus at these places.

As discussed above, when the metal lead terminals 11 and 12 are erected passing through the base main body 10 with the insulating glass G interposed in between, as shown in FIGS. 7, 8, and 9 in particular, a meniscus is formed by the insulating glass G at the places where it joins with the metal lead terminals 11 and 12. This meniscus formation by the insulating glass G allows the metal lead terminals 11 and 12 to be properly centered at the positions where they are to be erected on the base main body 10, and allows the metal lead terminals 11 and 12 to be formed at the desired positions of the base main body 10. Furthermore, as shown in FIGS. 8 and 9, because the insulating glass G forms a meniscus at the places where it joins with part of the side faces or the bottom faces of the nail-head parts 11a and 12a, the centering of the erection positions of the metal lead 11 and 12 on the base main body 10 can be carried out more accurately than when a meniscus is formed at another portion of the metal lead 11 and 12. Therefore, with the configuration shown in FIGS. 8 and 9, the metal 11 and 12 can be formed at the desired positions on the base main body 10, and joint strength can be increased.

Also, with this example, the electroconductive resin adhesive S is used for the direct electrical connecting and mechanical joining of the piezoelectric resonator plate 2 (the excitation electrodes 21 and 22 and the take-off electrodes 21a and 22a) to the upper faces of the nail-head parts 11a and 12a of the metal lead terminals 11 and 12, but the electroconductive resin adhesive S is not limited to this, and may be composed of two types of adhesive.

More specifically, a first electroconductive resin adhesive (such as a modified epoxy-based electroconductive resin adhesive) may be used to ensure conductivity of the take-off electrodes 21a and 22a to the nail-head parts 11a and 12a and to tack the piezoelectric resonator plate 2 to the nail-head parts 11a and 12a, and after the piezoelectric resonator plate 2 has been directly and electro-mechanically tacked to the nail-head parts 11a and 12a by the first electroconductive resin adhesive, a second electroconductive resin adhesive may be used for the direct electrical connecting and mechanical joining of the nail-head parts 11a and 12a with the ends of the long sides of the piezoelectric resonator plate 2, thereby attaching (placing) the piezoelectric resonator plate 2 to the nail-head parts 11a and 12a. In this case, at the junction interface between the first electroconductive resin adhesive used for tacking and the second electroconductive resin adhesive used for main joining, the metal filler components contained in each will work their way into each other, producing an anchoring effect, which not only increases the mechanical joint strength, but also ensures a good electrical conduction path and thereby improves conduction performance. Therefore, the impact resistance and conduction performance of the crystal resonator according to Example 1 can be enhanced even further.

For example, a modified epoxy-based electroconductive resin adhesive may be used as the first electroconductive resin adhesive, and a silicone-based electroconductive resin adhesive may be used as the second electroconductive resin adhesive. Compared to when just a modified epoxy-based electroconductive resin adhesive is used, the hardness of the modified epoxy-based electroconductive resin adhesive will have less of an effect (effects such as deterioration in impact resistance and DLD characteristics), resulting in a better state. Or, an electroconductive resin adhesive including a modified epoxy-based electroconductive resin adhesive and a silicone-based electroconductive resin adhesive laminated in that order may be used as the first electroconductive resin adhesive, and a silicone-based electroconductive resin adhesive may be used as the second electroconductive resin adhesive. In this case, the hardness of the modified epoxy-based electroconductive resin adhesive and the hardness of the silicone-based electroconductive resin adhesive will affect the hardness of the first electroconductive resin adhesive, so it is preferable to use a modified epoxy-based electroconductive resin adhesive as the first electroconductive resin adhesive and use a silicone-based electroconductive resin adhesive as the second electroconductive resin adhesive.

### Example 2

Next, a crystal resonator according to Example 2 will be described through reference to the drawings. The difference between the crystal resonators in Examples 1 and 2 is in the configuration of the nail-head parts. In view of this, only the configuration of Example 2 that differs from Example 1 above will be described, and the configurations that are the same will not be described again. Therefore, the effects and modification examples according to the same configuration will be the same as those of Example 1 above.

As shown in FIG. 10, with Example 2 rough parts 11b and 12b are formed on the upper faces of the nail-head parts 11a (the region joined with the electroconductive resin adhesive S). The rough parts formed on the upper faces of the nail-head parts may be formed on just part of the upper face as with the rough part 11a, or may be formed over the entire upper face as with the rough part 12b.

The rough parts 11b and 12b can be formed by stamping simultaneously with the nail-head parts 11a and 12a, or can be formed separately by etching, dimpling, grinding, or another such method.

As a specific example of the dimensions of the lead terminal portions shown in FIG. 10, the diameter of the lead terminals 11 and 12 is set to about 0.32 to 0.45 mm, while the width d of the nail-head parts 11a and 12a is set to about 0.7 to 0.9 mm. The rough parts 11b and 12b are set to a maximum surface roughness of about 6 to 30 μm, as measured by a method that measures roughness from the maximum height. The average surface roughness of the rough parts 11b and 12b is set to between 0.1 and 2 μm (and desirably 0.1 to 1 μm). The surface roughness here is measured as set forth in JIS B 0601. If the average surface roughness is less than 0.1 μm, this is defined in this example as having a mirror finish, and if the average surface roughness is over 2 μm, this is defined as being bumpy, rather than just rough.

Although not shown in the drawings, the metal portions exposed on the surface of the base 1 and the metal lead terminals 11 and 12 are given an inexpensive and practical nickel plating film to prevent corrosion. In particular, in Example 2, a nickel electroplating film is formed in a thickness of about 4 to 6 μm by an electrolytic plating method, and an electroless nickel plating film is formed over this in a thickness of about 2 to 5 μm by an electroless plating method. A nickel electroplating film has a higher melting point than an electroless nickel plating film, and an anticorrosive function before and after firing can be obtained by forming this film prior to the firing of the insulating glass G. The electroless nickel plating film is formed as a film with more uniform quality than the nickel electroplating film, so not only does it improve wettability with solder and the like, but it results in an amorphous structure in which phosphorus, boron, and so forth originating in a reducing agent are co-deposited on the uppermost surface, and this yields an anticorrosive film that is hard and has better corrosion resistance. In other words, the electroless nickel plating film serves as an anticorrosive film on the uppermost surface of the base 1 and the metal lead terminals 11 and 12, providing high reliability and extremely good practicality despite a low cost, but a problem is that conduction resistance at the junction interface with the electroconductive resin adhesive S tends to be increased by the adverse effect of an oxidation layer. However, in Example 2, these problems can be ameliorated not only by combining with the electroconductive resin adhesive S, but also combining with the rough parts 11b and 12b.

The piezoelectric resonator plate 2 is then placed in a state in which the middle parts of its short sides are near the center of gravity of the nail-head parts 11a and 12a on the inner side of the metal lead terminals 11 and 12, the nail-head parts 11a and 12a and the ends of the long sides of the piezoelectric resonator plate 2 are directly and electromechanical joined via the electroconductive resin adhesive S having at least flexibility of a pencil hardness of 4B, and the piezoelectric resonator plate 2 is attached (placed) on the nail-head parts 11a and 12a. Here, the entire upper surface of the nail-head parts 11a and 12a is formed as the joining region with the electroconductive resin adhesive S. The distance between the centers of gravity of the nail-head parts 11a and 12a is set to 4.8 mm.

Also, a silicone-based electroconductive resin adhesive having flexibility greater than a pencil hardness of 4B (a pencil hardness of about 6B), or a modified epoxy-based electroconductive resin adhesive (a pencil hardness of about 4B) is used as the electroconductive resin adhesive S having at least flexibility of a pencil hardness of 4B. Preferably, the metal filler contained in the electroconductive resin adhesive S is in the form of flakes whose main component is silver or the like, and the average particle size of the metal filler is preferably from 3 to 6 μm. The result of this is that the there is a higher probability that the flakes of metal filler contained in the electroconductive resin adhesive S will come into contact with the nail-head parts 11a and 12a of the metal lead terminals, and conduction performance is more stably and reliably enhanced.

In Example 2 of the present invention, the device includes the base 1, through which the metal lead terminals 11 and 12 are erected via the insulating glass G, the piezoelectric resonator plate 2 that is rectangular in plan view, which is in the same direction as the plane of the metal base 1 and which is placed on the metal lead terminals 11 and 12 and on which are formed the excitation electrodes 21 and 22 that are electrically connected via the electroconductive resin adhesive S, and the metal lid 3 that hermetically covers (hermetically seals) the piezoelectric resonator plate 2 placed on the metal lead terminals 11 and 12; the electroconductive resin adhesive S has at least flexibility of a pencil hardness of 4B. An electroless nickel plating film (anticorrosive film) is formed on the outer surface of the metal base 1 and the metal lead terminals 11 and 12, the wide nail-head parts 11a and 12a on which the piezoelectric resonator plate 2 is placed are formed on the inner side of the metal lead terminals 11 and 12, the rough parts 11b and 12b with an average surface roughness of 0.2 to 2 μm (and desirably 0.1 to 1 μm) are formed in at least the region of the nail-head parts 11a and 12a that is joined with the electroconductive resin adhesive S, and the silicone-based or modified epoxy-based electroconductive resin adhesive S with flexibility greater than a pencil hardness of 4B is used for the direct electrical connecting and mechanical joining of the ends of the long sides of the piezoelectric resonator plate 2 to the upper parts of the rough parts 11b and 12b of the nail-head parts 11a and 12a. Therefore, better conduction can be ensured with the electrodes (such as the excitation electrodes 21 and 22) of the piezoelectric resonator plate 2 at the rough parts 11b and 12b of the nail-head parts 11a and 12a of the metal lead terminals 11 and 12. As a result, impact resistance performance is improved while conduction performance is also enhanced, thus eliminating the increase in the serial resonance resistance (CI value) of the crystal resonator, and affording an inexpensive crystal resonator with excellent electrical connectivity.

In contrast, in Patent Document 1 above, impact resistance is inferior to support structure with a support structure in which support members are interposed, and it is essential to use a soft, silicone-based electroconductive resin adhesive. However, a problem encountered with a constitution involving the use of a silicone-based electroconductive resin adhesive was that the nickel or other such anticorrosive film formed on the outer surface of the metal base and the metal lead terminals was adversely affected by an oxidation layer formed on the uppermost face of the anticorrosive film. That is, the effect of the oxidation layer was to raise the conduction resistance at the junction interface between the silicone-based electroconductive resin adhesive and the metal lead terminals, which sometimes diminished the conduction performance of the piezoelectric resonator device. As a result, the electrical performance, such as the serial resonance resistance (CI value), of the piezoelectric resonator device may suffer. However, these problems can be solved with the crystal resonator according to Example 2 as discussed above.

Even though the cushioning action is limited by the elimination of the supports, with the crystal resonator according to Example 2 constituted as above, impact resistance can be improved since the piezoelectric resonator plate 2 is attached to the nail-head parts 11a and 12a via the electroconductive resin adhesive S with flexibility of at least a pencil hardness of 4B, such as a silicone-based or modified epoxy-based electroconductive resin adhesive S with flexibility greater than a pencil hardness of 4B. And since the rough parts 11b and 12b with an average surface roughness of 0.2 to 2 μm is formed on the upper faces of the nail-head parts 11a and 12a (at least the region joined with the electroconductive resin adhesive S), an anchoring effect is produced by combination with the electroconductive resin adhesive S, which increases the joint strength of the piezoelectric resonator plate 2 and the nail-head parts 11a and 12a. Furthermore, this anchoring effect causes the metal filler contained in the electroconductive resin adhesive S to work its way toward the base material portion of the nail-head parts 11a and 12a of the metal lead terminals 11 and 12, and this improves the conduction performance by increasing the contact surface area between the metal filler and the nail-head parts 11a and 12a. Preferably, the metal filler is in the form of flakes, which improves how well it works its way in. In other words, all of the metal filler may be in the form of flakes, or a mixture of granular and flaked filler may be used.

If the above-mentioned surface roughness is less than 0.2 μm, the above-mentioned anchoring effect will be too weak to obtain satisfactory conduction performance. On the other hand, it is impractical for the surface roughness to be greater than 2 μm, because the anticorrosive film will be formed in a poor state, and as a result oxidation of the nail-head parts 11a and 12a and so forth will be more likely to occur.

Also, in Example 2, the metal filler contained is in the form of flakes, and the average particle size of the metal filler is 3 to 6 μm, which is less than the roughness of the rough parts, so the metal filler formed in a lower roughness than the nail-head parts 11a and 12a will work its way even better into the rough parts 11b and 12b of the nail-head parts 11a and 12a of the metal lead terminals 11 and 12, and an even better anchoring effect will be obtained. As a result, a more reliable conduction path will be ensured via the metal filler formed in a lower roughness than the rough parts 11b and 12b, so conduction performance is more stable and reliably higher.

Also, when the silicone-based electroconductive resin adhesive S is joined to the rough parts 11b and 12b of the nail-head parts 11a and 12a, then even when the device is put under a high-temperature environment at some point after the joining of the piezoelectric resonator plate, such as during a reflow step, the interaction of the anticorrosive film and the silicone-based electroconductive resin adhesive S reduces the likelihood of an adverse effect from an oxidation layer in an amorphous structure formed on the uppermost face of the electroless nickel plating film (anticorrosive film). As a result, conduction performance is better at the junction interface between the nail-head parts 11a and 12a and the electroconductive resin adhesive S, and there is less deterioration of the electrical performance, such as the serial resonance resistance (CI value), of the crystal resonator.

Also, when the silicone-based electroconductive resin adhesive S or the modified epoxy-based electroconductive resin adhesive S is used as the electroconductive resin adhesive S, even though the cushioning action is limited by the elimination of the supports, impact resistance can be improved since the piezoelectric resonator plate 2 is attached to the nail-head parts 11a and 12a via the silicone-based electroconductive resin adhesive S or the modified epoxy-based electroconductive resin adhesive S, which both have good flexibility. Also, when a modified epoxy-based electroconductive resin adhesive is joined to the rough parts 11b and 12b of the nail-head parts 11a and 12a, this further enhances the electrical connecting and mechanical joining between the nail-head parts 11a and 12a of the metal lead terminals 11 and 12 and the electrodes (such as the excitation electrodes 21 and 22) of the piezoelectric resonator plate 2.

Variations on Example 2

In Example 2, the rough parts 11b and 12b are formed on the upper faces of the nail-head parts 11a and 12a, which are the regions joined with the electroconductive resin adhesive S, but these may instead be formed over the entire nail-head parts 11a and 12a. Also, a laminated plating layer of silver flash plating, gold plating, or a combination of these may be formed over the nickel plating layer on at least the surface of the nail-head parts 11a and 12a, which reduces the adverse effect of the oxidation layer formed on the electroless nickel plating film or other anticorrosive film, and improves conduction performance at the junction interface with the electroconductive resin adhesive.

### Example 3

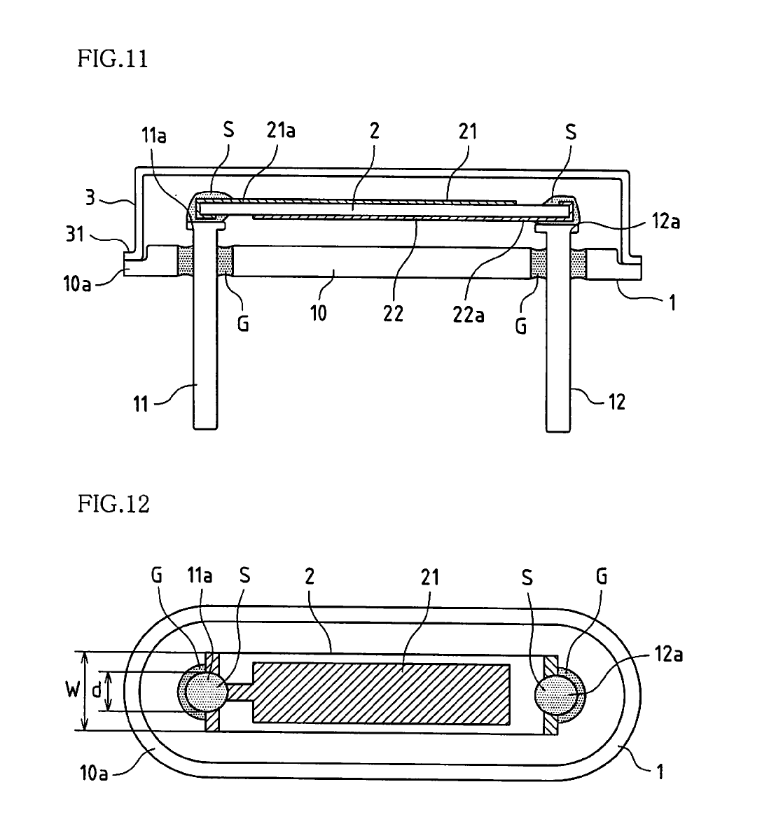

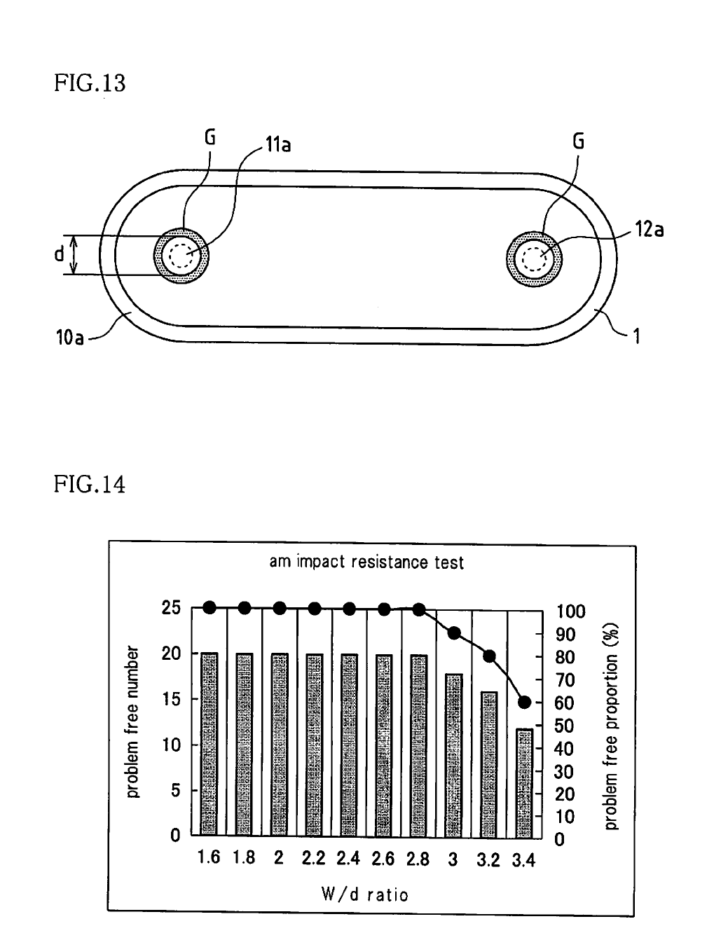

Next, the piezoelectric resonator device according to Example 3 will be described through reference to the drawings, using a crystal resonator as an example. FIG. 11 is a simplified cross-sectional view of a crystal resonator according to Example 3, FIG. 12 is a simplified plan view of the base prior to covering with the lid in FIG. 11, and FIG. 13 is a simplified plan view of the base prior to putting the piezoelectric resonator plate in place in FIG. 12.

The crystal resonator according to Example 3 has the same constitution as the crystal resonators according to Examples 1 and 2 above. Therefore, in Example 3, the configurations that are the same as those in Examples 1 and 2 will be numbered the same, the effects and modification examples according to the same configuration will be the same as those of Examples 1 and 2.

A piezoelectric resonator plate 2 includes an AT cut crystal resonator plate, and is worked into a rectangular shape in plan view, consisting of short and long sides. The front and back faces (main faces) thereof are provided with excitation electrodes 21 and 22 and take-off electrodes 21a and 22a by vacuum vapor deposition or another such means. For electrical connection (discussed below) to be carried out reliably, the take-off electrodes 21a and 22a are each wrapped around to the other main face. As to the electrode materials, a laminated structure including one or more main electrode layers whose main component is silver or gold is formed on top of a base electrode layer of chromium or nickel. With the piezoelectric resonator plate 2 according to Example 1, the length of the long sides thereof in plan view is set to 5.0 mm, and the length of the short sides thereof in plan view is set to between 1.5 and 2.5 mm.

A base 1 (the metal base in the present invention) has an oval cylinder shape that is short in height overall, and metal lead terminals 11 and 12 are erected passing through a base main body 10 that mainly includes a metal shell. The metal lead terminals 11 and 12 are erected passing through insulating glass G that is packed into part of the base main body 10. The metal lead terminals 11 and 12 are erected opposite each other on the base main body 10, and the metal lead terminals 11 and 12 are electrically independent of one another. A peripheral flange 10a is integrally provided to the lower peripheral edge portion of the base main body 10. A peripheral projection (not shown) is integrally formed on the flange 10a.

The metal lead terminals 11 and 12 are in the form of a slender cylinder composed of Kovar or the like, and nail-head parts 11a and 12a that are wide and whose upper part is flat and substantially circular in plan view are formed at the ends on the inner side of the upper part of the base 1. These nail-head parts 11a and 12a are formed by stamping or another process that takes advantage of the ductility of metal. As an example of the specific dimensions of the metal lead terminals 11 and 12, the diameter of the metal lead terminals 11 and 12 is about 0.32 to 0.45 mm, while the width d of the nail-head parts 11a and 12a is about 0.7 to 0.9 mm. The term “inner” as used above means the interior space formed by the joining of the base 1 and a lid 3 (see below), which is hermetically sealed to include the piezoelectric resonator plate 2 placed on the base 1. “On the inner side” means portions of the metal lead terminals 11 and 12 erected passing through the base 1 and located inside the hermetically-sealed interior space.

Although not shown in the drawings, the metal portions exposed on the surface of the base 1 and the metal lead terminals 11 and 12 are given an inexpensive and practical nickel plating film to prevent corrosion. In particular, in Example 3, a nickel electroplating film is formed in a thickness of about 4 to 6 μm by an electrolytic plating method, and an electroless nickel plating film is formed over this in a thickness of about 2 to 5 μm by an electroless nickel plating method. A nickel electroplating film has a higher melting point than an electroless nickel plating film, and an anticorrosive function before and after firing can be obtained by forming this film prior to the firing of the insulating glass G. The electroless nickel plating film is formed as a film with more uniform quality than the nickel electroplating film, so not only does it improve wettability with solder and the like, but it results in an amorphous structure in which phosphorus, boron, and so forth originating in a reducing agent are co-deposited on the uppermost surface, and this yields an anticorrosive film that is hard and has better corrosion resistance.

Also, erecting the metal lead terminals 11 and 12 passing through the base main body 10 via the insulating glass G causes the insulating glass G to form a meniscus at the joint with the metal lead terminals 11 and 12, as shown in FIG. 11. When the insulating glass G forms this meniscus, the positions where the metal lead terminals 11 and 12 are erected on the base main body 10 can be centered, allowing the metal lead terminals 11 and 12 to be formed at the desired locations on the base main body 10.

The metal lid 3 has an oval cylinder shape and is open at the bottom, and this open portion has a flange 31 corresponding to the flange 10a of the base. The flange 31 of this lid 3 is resistance welded to the base 1 (more specifically, to the flange 10a), which joins it to the base 1 and forms a packaged crystal resonator. Resistance welding the lid 3 to the base 1 hermetically seals the interior space of the package. The “inner side” of the metal lead terminals 11 and 12 refers to the portions of the metal lead terminals 11 and 12 on the inside of the hermetic seal.

Prior to the direct electrical connecting and mechanical joining of the piezoelectric resonator plate 2 with the nail-head parts 11a and 12a on the inner side of the metal lead terminals 11 and 12 via the electroconductive resin adhesive S, the outer surface of the base 1 is treated with acid.

More specifically, in Example 1 the acid treatment of the nickel plating film is accomplished by washing with dilute hydrochloric acid, for example. The oxidation layer on the upper face of the electroless nickel plating film (anticorrosive film) is removed or only remains in places by the washing on the outer surface of the base 1 (the metal lead terminals 11 and 12 and the base main body 10) washed with this dilute hydrochloric acid.

After acid washing, the metal surface has either had the oxidation film removed, or the oxidation film is only left in places, so this surface is in a state of extremely high activity. When the base 1 is left in this state, an oxidation film of the metal surface will be formed again on the base 1, which has the adverse effect of increasing the thickness thereof. Therefore, before there is an increase in thickness to a thickness that is adversely affected by the oxidation film from the base 1 in this state, the piezoelectric resonator plate 2 is placed so that the middle parts of its short sides are placed near the center of gravity of the nail-head parts 11a and 12a on the inner side of the metal lead terminals 11 and 12, the nail-head parts 11a and 12a and the ends of the long sides of the piezoelectric resonator plate 2 are directly electro-mechanically joined via the modified epoxy-based electroconductive resin adhesive S having flexibility greater than a pencil hardness of 4B, and the piezoelectric resonator plate 2 is attached (placed) on the nail-head parts 11a and 12a. Here, the entire upper surface of the nail-head parts 11a and 12a is formed as the joining region with the electroconductive resin adhesive S, and the width W of the short sides of the piezoelectric resonator plate 2 is set to be not more than 2.8 times the width d of the nail-head parts 11a and 12a in the same direction.

As discussed above, the piezoelectric resonator device of Example 3 includes the base 1, the piezoelectric resonator plate 2, and the lid 3, an anticorrosive film (electroless nickel plating film) is formed on the outer surface of the metal lead terminals 11 and 12 and the base 1, an oxidation layer of the anticorrosive film is formed on the upper face of this anticorrosive film, and an electroconductive resin adhesive S with flexibility greater than a pencil hardness of 4B is used for the direct electrical connecting and mechanical joining of the piezoelectric resonator plate 2 to the upper face of the oxidation layer of the anticorrosive film, on the inner side of the metal lead terminals 11 and 12, in a state in which the oxidation layer of at least the portion coated with the electroconductive resin adhesive S is thinner than the oxidation layer in the other region, or a state in which the oxidation film is present only in places.

As a specific example of the dimensions of the above constitution, first, the distance between the centers of gravity of the nail-head parts 11a and 12a is set to 4.8 mm. If the width d of the nail-head parts 11a and 12a is from 0.7 to 0.9 mm, then the width W of the short sides of the piezoelectric resonator plate 2 can be set smaller than, respectively, from 1.96 to 2.52 mm, and placement will be stable when the piezoelectric resonator plate 2 is joined to the nail-head parts 11a and 12a. Also, the joint strength between the piezoelectric resonator plate 2 and the nail-head parts 11a and 12a will be stable, and there will be no twisting whatsoever in the short side portions of the piezoelectric resonator plate 2 during impact. This prevents problems of the cracking of the piezoelectric resonator plate 2 and the separation of the electroconductive resin adhesive S from the nail-head parts 11a and 12a of the metal lead terminals 11 and 12, and will lead to absolutely no decrease in electrical characteristics of the crystal resonator, or to ceased oscillation. When conventional supports are used, because the supports themselves are so wide, it is impossible to place a piezoelectric resonator plate with a large ratio of 2.8 times for the width of the short sides of the piezoelectric resonator plate to the width of the supports. In contrast, with Example 3, since the supports are eliminated and the piezoelectric resonator plate 2 is placed directly on the nail-head parts 11a and 12a, a piezoelectric resonator plate 2 of the existing size can be used, and can fit in a package (the hermetically sealed interior space of a package consisting of the base 1 and the lid 3).

The width d of the nail-head parts 11a and 12a must be suitably adjusted according to the width W of the short sides of the piezoelectric resonator plate. Also, while not depicted, in Example 3 the region joined with the electroconductive resin adhesive S is determined by the width d of the nail-head parts 11a and 12a. However, a region of coating with the electroconductive resin adhesive S (joined region) may be formed on part of the upper faces of the nail-head parts 11a and 12a, and the width W of the short sides of the piezoelectric resonator plate 2 may be specified based on the width of the coated region thus formed (the short side direction of the piezoelectric resonator plate).

Also, a urethane-modified epoxy-based electroconductive resin adhesive (such as one from the XA-471B-3 series made by Fujikura Kasei), for example, was used as the modified epoxy-based electroconductive resin adhesive S with flexibility greater than a pencil hardness of 4B. The result of forming in this way is that the piezoelectric resonator plate 2 and the metal lead terminals 11 and 12 can be joined without being affected by the oxidation layer on the upper face of the electroless nickel plating film (anticorrosive film). In particular, adhesive strength is increased for a thin oxidation film on the resin part of the electroconductive resin adhesive S, or for an oxidation film that is present only in places. As a result, there is a higher probability of contact between the metal filler of the electroconductive resin adhesive S and the base material portion of the metal lead terminals 11 and 12, and not only does conduction performance improve, but the mechanical joint strength also increases.

The metal filler contained in the electroconductive resin adhesive S preferably is in the form of flakes whose main component is silver or the like, and the average particle size of the metal filler is preferably from 3 to 6 μm. The result of this is that the there is a higher probability that the flakes of metal filler contained in the electroconductive resin adhesive S will come into contact with the nail-head parts 11a and 12a of the metal lead terminals, and conduction performance is more stably and reliably enhanced.

After placement of the piezoelectric resonator plate 2 on the base 1 using the above constitution, annealing and other such necessary treatments are performed. After this, the base 1 is covered with the lid 3, and although not depicted, welding electrodes are brought into contact with the flanges 10a and 31 and pressure is applied to them while current is allowed to flow and resistance welding performed, which completes the hermetic sealing of the package consisting of the base 1 and the lid 3.

The crystal resonator of Example 3 includes the base 1, the piezoelectric resonator plate 2, and the lid 3, the piezoelectric resonator plate 2 has a rectangular shape in plan view and is placed on the metal lead terminals 11 and 12 with the main face thereof facing in the same direction as the plane of the base 1, wide nail-head parts 11a and 12a on which the piezoelectric resonator plate 2 is placed are formed at the end portions of the metal lead terminals 11 and 12 hermetically sealed (on the inner side of the metal lead terminals 11 and 12), the piezoelectric resonator plate 2 is attached at both ends of its long sides via the electroconductive resin adhesive S in a state in which the middle parts of the short sides of the piezoelectric resonator plate 2 are placed near the location of the center of gravity of the nail-head parts 11a and 12a, and the width of the piezoelectric resonator plate 2 in its short side direction is set to not more than 2.8 times the width of the region of the nail-head parts 11a and 12a on the top portion thereof in the same direction that is joined with the electroconductive resin adhesive S.

In contrast, in Patent Document 1 above, impact resistance is inferior to that with a support structure in which support members are interposed, and problems of the cracking of the piezoelectric resonator plate and the separation of the electroconductive resin adhesive from the metal lead terminals are more pronounced. With a conventional crystal resonator, these problems can lead to diminished electrical characteristics of the crystal resonator, and in severe cases they can even prevent the crystal resonator from oscillating. However, these problems can be solved with the crystal resonator according to Example 3 as discussed above.

That is, Example 3 is a sealed terminal type of crystal resonator in which the base 1 equipped with the metal lead terminals 11 and 12, which are hermetically sealed and therefore highly reliable, is covered and hermetically sealed with the lid 3, and eliminating the support members contributes greatly to both a shorter height and a lower cost. Furthermore, since the wide nail-head parts 11a and 12a on which the piezoelectric resonator plate 2 is placed are formed at the end portions on the inner side of the metal lead terminals 11 and 12, and the piezoelectric resonator plate 2 is attached at both ends of its long sides via the electroconductive resin adhesive S in a state in which the middle parts of the short sides of the piezoelectric resonator plate 2 are near the location of the center of gravity of the nail-head parts 11a and 12a, and the width of the piezoelectric resonator plate 2 in its short side direction is set to not more than 2.8 times the width of the region of the nail-head parts 11a and 12a on the top portion thereof in the same direction that is joined with the electroconductive resin adhesive S, placement of the crystal resonator is stable when it is joined to the nail-head parts 11a and 12a. Also, because the short sides of the piezoelectric resonator plate 2 are set to not more than 2.8 times the width of the region of the nail-head parts 11a and 12a on the top portion thereof that is joined with the electroconductive resin adhesive S, the joint strength between the piezoelectric resonator plate 2 and the nail-head parts 11a and 12a is also stable, and twisting of the short side portions of the piezoelectric resonator plate 2 during impact is completely eradicated. This prevents problems of the cracking of the piezoelectric resonator plate 2 and the separation of the electroconductive resin adhesive S from the nail-head parts 11a and 12a of the metal lead terminals 11 and 12, and also eliminates any decrease in electrical characteristics of the crystal resonator and prevents a stop of oscillation. In other words, this improves the impact resistance of the crystal resonator.

Also, with Example 3, since the region of the nail-head parts 11a and 12a joined with the electroconductive resin adhesive S is formed over the entire upper face of the nail-head parts 11a and 12a, and the width of the piezoelectric resonator plate 2 in its short side direction is set to not more than 2.8 times the width of the nail-head parts 11a and 12a in the same direction, setting the region of joining with the electroconductive resin adhesive S is extremely easy by specifying the shape of the upper part of the nail-head parts 11a and 12a, and even if the electroconductive resin adhesive S should be applied in an excessive amount, the electroconductive resin adhesive S will work its way around to the lower side of the nail-head parts 11a and 12a, so there will be no variance at all in the width or surface area of the region of joining with the electroconductive resin adhesive S. Also, with the above structure of the nail-head parts 11a and 12a, compared to a structure that makes use of supports, the support portions will not undergo bending deformation, so the position of the placement site in the height direction will be stable, and the amount in which the nail-head parts 11a and 12a are coated with the electroconductive resin adhesive S will also be stable. As discussed above, the dimensions of the region of the nail-head parts 11a and 12a joined with the electroconductive resin adhesive S to the short sides of the piezoelectric resonator plate 2 can be specified extremely easily and reliably. In particular, with a structure in which the piezoelectric resonator plate 2 is joined directly to the upper part of the metal lead terminals 11 and 12, it was difficult to specify the shape, width, etc., of the region of joining with the electroconductive resin adhesive S, but these can be specified extremely easily and reliably by combining a structure in which the electroconductive resin adhesive S is formed over the entire upper face of the nail-head parts 11a and 12a.

FIG. 14 shows the results of an impact resistance test on a crystal resonator with the sealed terminal structure shown in FIG. 11, in which the electroconductive resin adhesive S was formed over the entire upper face of the nail-head parts 11a and 12a, and the ratio of the width W of the short side of the crystal resonator plate 2 to the diameter d of the nail-head parts 11a and 12a was varied from 1.6 to 3.4 times. In this test, a silicone resin-based electroconductive adhesive was used as the electroconductive resin adhesive S to join the nail-head parts 11a and 12a and the piezoelectric resonator plate 2, samples of the crystal resonator set to the above-mentioned W/d ratios were dropped three times from a height of 150 cm, and the samples were then checked to find the problem-free proportion of the resonators in which the serial resonance resistance (CI value) of the crystal resonator had risen, or there was frequency fluctuation, or oscillation had ceased. As is clear from these results, when the W/d ratio was between 1.6 and 2.8 times, the problem-free proportion was 100%, whereas when the W/d ratio was 3 times, this proportion dropped to 90%, and when the W/d ratio was 3.2 times, this proportion dropped to 80%, and when the W/d ratio was 3.4 times, this proportion dropped to 60%. This revealed that excellent impact resistance was obtained for samples in which the width W in the short side direction of the crystal resonator plate 2 was set to within 2.8 times the width d of the nail-head parts 11a and 12a in the same direction.

Even though the cushioning action is limited by the elimination of the supports, impact resistance can be improved since the piezoelectric resonator plate 2 is attached to the nail-head parts 11a and 12a via the electroconductive resin adhesive S with flexibility of at least a pencil hardness of 4B. Also, when the electroconductive resin adhesive S is used, a passivation film formed on top of the anticorrosive film will have no adverse effect even when the device is put under a high-temperature environment at some point after the joining of the piezoelectric resonator plate 2, such as during a reflow step, and conduction performance will be improved at the junction interface between the nail-head parts 11a and 12a and the electroconductive resin adhesive S. That is, without special machining for an ordinary lead terminal on which only an anticorrosive film is formed, conduction performance can be improved between the nail-head parts 11a and 12a and the piezoelectric resonator plate 2, and the electrical performance, such as the serial resonance resistance (CI value), of the crystal resonator, can be improved, with a less expensive structure.

In Example 3 above, the electroconductive resin adhesive S having flexibility of at least a pencil hardness of 4B is used, and this is a material with good DLD characteristics and impact resistance, which would otherwise be lost because of the elimination of the supports used in prior art, and is a material that also improves conduction characteristics when the constitution of Example 3 is included. Usually, DLD characteristics and impact resistance are mutually exclusive from conduction characteristics, and only one or the other can be achieved with an ordinary electroconductive adhesive. However, the electroconductive resin adhesive S according to Example 3 makes it possible to achieve good impact resistance, DLD characteristics, and conduction characteristics.

Also, in Example 3, an anticorrosive film is formed on the outer surface of the metal lead terminals 11 and 12 and the base 1, an oxidation layer of the anticorrosive film is formed on the upper face of this anticorrosive film, and on the inner side of the metal lead terminals 11 and 12, an electroconductive resin adhesive S with flexibility greater than a pencil hardness of 4B is used for the direct electrical connecting and mechanical joining of the piezoelectric resonator plate 2 to the upper face of the oxidation layer of the anticorrosive film in a state in which the oxidation layer of at least the portion coated with the electroconductive resin adhesive S is thinner than the oxidation layer in the other region, or a state in which the oxidation film is present only in places. Therefore, more reliable conduction to the electrodes of the piezoelectric resonator plate 2 can be ensured in the portions coated with the electroconductive resin adhesive S on the inner side of the metal lead terminals 11 and 12. As a result, impact resistance performance is improved while conduction performance is also enhanced, thus eliminating the increase in the serial resonance resistance (CI value) of the piezoelectric resonator device, and affording an inexpensive piezoelectric resonator device with excellent electrical connectivity.

That is, since the electroconductive resin adhesive S with flexibility greater than a pencil hardness of 4B is used for the direct electrical connecting and mechanical joining of the piezoelectric resonator plate 2 to the upper face of the oxidation layer of the anticorrosive film, on the inner side of the metal lead terminals 11 and 12, in a state in which the oxidation layer of at least the portion coated with the electroconductive resin adhesive S is thinner than the oxidation layer in the other region, or a state in which the oxidation film is present only in places, the adhesive strength of the resin component of the electroconductive resin adhesive S is increased for a thin oxidation film, or for an oxidation film that is present only in places. As a result, there is a higher probability of contact between the metal filler and the base material portion of the metal lead terminals 11 and 12, and conduction performance is improved.

Also, in Example 3, the method for manufacturing this piezoelectric resonator device includes a step of forming an anticorrosive film on the outer surface of the base 1 and the metal lead terminals 11 and 12, a step of washing the outer surface of the base 1 and the metal lead terminals 11 and 12 with dilute hydrochloric acid and then coating the inner side of the metal lead terminals 11 and 12 with an electroconductive resin adhesive S with flexibility greater than a pencil hardness of 4B, and a step of placing the ends of the piezoelectric resonator plate 2 on the inner side of the metal lead terminals 11 and 12 coated with the electroconductive resin adhesive S, and directly electro-mechanically joining the piezoelectric resonator plate 2 with the inner side of the metal lead terminals 11 and 12 via the electroconductive resin adhesive S, so the outer surface of the metal base 1 and the metal lead terminals 11 and 12 washed with dilute hydrochloric acid is in a state in which the oxidation layer on the upper face of the anticorrosive film has been removed or only remains in places.

Accordingly, in Example 3, the piezoelectric resonator plate 2 and the metal lead terminals 11 and 12 are joined in a state of being adversely unaffected by the oxidation layer formed on the upper face of the anticorrosive film. In particular, the adhesive strength of the resin component of the electroconductive resin adhesive S is increased for the thinner oxidation film or the oxidation film present only in places. As a result, there is a higher probability of contact between the metal filler and the base material portion of the metal lead terminals 11 and 12, and conduction performance is improved.

After this, at least on the other outer surface of the metal base 1 or the metal lead terminals 11 and 12 not coated with the electroconductive resin adhesive S, and on the inner side of the metal lead terminals 11 and 12, the thickness of the oxidation layer formed on the upper face of the anticorrosive film increases, so its function of preventing corrosion is enhanced.

In Example 3, a modified epoxy-based electroconductive resin adhesive having flexibility greater than a pencil hardness of 4B is used as the electroconductive resin adhesive S, but the present invention is not limited to this, and the electroconductive resin adhesive S may be any type that has flexibility of at least a pencil hardness of 4B. For instance, it may be a silicone-based electroconductive resin adhesive with a pencil hardness of 6B, which is more flexible than one with a pencil hardness of 4B. It may also be a modified epoxy-based electroconductive resin adhesive with a pencil hardness of 4B (see below).

### Other Examples

In Example 3, a modified epoxy-based electroconductive resin adhesive is used as the electroconductive resin adhesive S, but the present invention is not limited to this, and a silicone-based, urethane-based, or epoxy-based electroconductive resin adhesive can be used instead. When a silicone-based electroconductive resin adhesive S is used, a laminated plating layer of silver flash plating, gold plating, or a combination of these is preferably formed over the nickel plating layer on at least the surface of the nail-head parts 11a and 12a. The reason for this is that it reduces the adverse effect of the passivation film formed on the nickel plating or other such anticorrosive film, and eliminates any decrease in conduction performance at the junction interface between the silicone-based electroconductive resin adhesive S and the nail-head parts 11a and 12a.

When an epoxy-based electroconductive resin adhesive S is used, it is preferable to use a modified epoxy-based electroconductive resin adhesive S with high flexibility of a pencil hardness of 4B or greater. The reason for this is that impact resistance can be increased, and conduction performance can be improved at the junction interface between the modified epoxy-based electroconductive resin adhesive S and the nail-head parts 11a and 12a, without adverse effect of the passivation film formed on the nickel plating or other such anticorrosive film.

Also, at least one of surface roughing, forming holes, grooves, or slits may be performed on at least the upper faces of the nail-head parts 11a and 12a. Employing this constitution improves the junction interface between the nail-head parts 11a and 12a and the electroconductive resin adhesive S, and increases the electromechanical joint strength of the electroconductive resin adhesive S between the piezoelectric resonator plate 2 and the nail-head parts 11a and 12a. Furthermore, when holes, grooves, or slits are formed in the upper faces of the nail-head parts 11a and 12a, this allows the electroconductive resin adhesive S to puddle and reduces its out-flow, so the coating amount of the electroconductive resin adhesive S is stabilized, which not only stabilizes the electro-mechanical joint strength of the electroconductive resin adhesive S, but also eliminates shorting with the metal portion of the base 1.

Also, as shown in FIG. 11, the upper faces of the nail-head parts 11a and 12a may be curved in a concave shape as shown in FIG. 6, for example. Here again, this allows the electroconductive resin adhesive S to puddle and reduces its out-flow, so the coating amount of the electroconductive resin adhesive S is stabilized, which not only stabilizes the electro-mechanical joint strength of the electroconductive resin adhesive S, but also eliminates shorting with the metal portion of the base 1.

The constitutions given as examples in the above embodiments can also be combined with one another. A crystal resonator was given as an example of the piezoelectric resonator device of the present invention, but it may instead be a crystal filter, crystal oscillator, or the like.

Furthermore, the present invention can be worked in a variety of other forms without departing from the essence or the main features thereof. Therefore, the embodiments given above are in all respects nothing more than examples, and should not be construed as being limiting. The scope of the present invention is indicated by the Claims, and not in any way restricted by the text of this Specification. Moreover, all changes and modifications belonging to the equivalent range of the Claims are within the scope of the present invention.

This application claims priority rights on the basis of Japanese Patent Application 2007-032019 submitted in Japan on Feb. 13, 2007, and Japanese Patent Applications 2007-048704 and 2007-048705 submitted in Japan on Feb. 28, 2007. The entire content thereof is incorporated into the present application by reference thereto.

### INDUSTRIAL APPLICABILITY

The piezoelectric resonator device according to the present invention is favorable when crystal is used as a piezoelectric material. In particular, the constitutions given as examples above can also be combined with one another. A crystal resonator was given as an example of the piezoelectric resonator device of the present invention, but it may instead be a crystal filter, crystal oscillator, or the like.

1. A piezoelectric resonator device, comprising:
a metal base through which at least two metal lead terminals are erected via an insulating material, a piezoelectric resonator plate that is placed on the metal lead terminals and is electrically connected to the metal lead terminals via an electroconductive resin adhesive, and a metal lid that hermetically covers the piezoelectric resonator plate placed on the metal lead terminals,
wherein the electroconductive resin adhesive has flexibility of at least a pencil hardness of 4B,
an anticorrosive film is formed on the outer surface of the metal base and the metal lead terminals, and
the electroconductive resin adhesive is used for the direct electrical connecting and mechanical joining of the ends of the piezoelectric resonator plate to the upper face of the anticorrosive film of the metal lead terminals hermetically sealed.

2. The piezoelectric resonator device according to claim 1,
wherein wide nail-head parts on which the piezoelectric resonator plate is placed are formed on the metal lead terminals hermetically sealed,
a rough part with an average surface roughness of 0.2 to 2 μm is formed in at least a region of the nail-head part that is joined with the electroconductive resin adhesive, and
the electroconductive resin adhesive is used for the direct electrical connecting and mechanical joining of the ends of the piezoelectric resonator plate to the rough parts of the nail-head parts.

3. The piezoelectric resonator device according to claim 2,
wherein the average particle size of a metal filler contained in the electroconductive resin adhesive is from 3 to 6 μm.

4. The piezoelectric resonator device according to claim 1,
wherein a silicone-based electroconductive resin adhesive or a modified epoxy-based electroconductive resin adhesive is used as the electroconductive resin adhesive.

5. A piezoelectric resonator device, comprising:
a metal base through which at least two metal lead terminals are erected via an insulating material, a piezoelectric resonator plate that is placed on the metal lead terminals and is electrically connected to the metal lead terminals via an electroconductive resin adhesive, and a metal lid that hermetically covers the piezoelectric resonator plate placed on the metal lead terminals,
wherein the piezoelectric resonator plate has a rectangular shape in plan view, and is placed on the metal lead terminals with the main face thereof facing in the same direction as the plane of the metal base,
wide nail-head parts on which the piezoelectric resonator plate is placed are formed at the end portions of the metal lead terminals hermetically sealed, and the piezoelectric resonator plate is attached at both ends of its long sides via the electroconductive resin adhesive in a state in which the middle parts of the short sides of the piezoelectric resonator plate are placed near the location of the center of gravity of the nail-head parts, and
the width of the piezoelectric resonator plate in its short side direction is set to not more than 2.8 times the width of a region of the nail-head part on the top portions thereof in the same direction that is joined with the electroconductive resin adhesive.

6. The piezoelectric resonator device according to claim 5,
wherein the region of the nail-head part that is joined with the electroconductive resin adhesive is formed over the entire upper face of the nail-head part, and
the width of the piezoelectric resonator plate in its short side direction is set to not more than 2.8 times the width of the nail-head part in the same direction.

7. The piezoelectric resonator device according to claim 5,
wherein an anticorrosive film is formed at least on the outer surface of the two metal lead terminals and the metal base, and
a silicone-based electroconductive resin adhesive is used for electrical connecting and mechanical joining of the ends of the long sides of the piezoelectric resonator plate to the nail-head parts in a state in which one of silver and gold plating has been formed at least on the surface of the nail-head parts at the upper face of the anticorrosive film.

8. The piezoelectric resonator device according to claim 5,
wherein the electroconductive resin adhesive has flexibility of at least a pencil hardness of 4B,
the anticorrosive film is formed at least on the outer surface of the metal base and the two metal lead terminals, and
the electroconductive resin adhesive is used for electrical connecting and mechanical joining of the ends of the long sides of the piezoelectric resonator plate to the nail-head parts at the upper face of the anticorrosive film.
